(19) United States
(12) Patent Application Publication
(10) Pub. No.: US 2006/0182993 A1
(43) Pub. Date: Aug. 17, 2006

(54) COMPOSITIONS FOR ORGANIC ELECTROLUMINESCENT DEVICE AND ORGANIC ELECTROLUMINESCENT DEVICE

(75) Inventors: Tomoyuki Ogata, Yokohama-shi (JP); Minoru Soma, Yokohama-shi (JP); Koichiro Ilda, Yokohama-shi (JP); Toshimitsu Nakai, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI CHEMICAL CORPORATION, Tokyo (JP)

(21) Appl. No.: 11/278,772

(22) Filed: Apr. 5, 2006

(30) Foreign Application Priority Data
Aug. 11, 2004 (JP) 2004-234438
Aug. 11, 2004 (JP) 2004-233676

(51) Int. Cl. H01L 51/50; H01L 51/56; C09D 7/00

(52) U.S. Cl. 428/690; 428/917; 313/504; 313/506; 427/66; 106/311

(57) ABSTRACT

Disclosed are compositions for an organic electroluminescent device favorably used for forming a hole injection layer and a hole transport layer of the organic electroluminescent device by a wet film forming method. The compositions for the organic electroluminescent device, which are composite solutions prepared by dissolving hole transport materials such as aromatic diamine compounds and an electron acceptor such as tri(pentafluorophenyl)boron in a solvent that contains an ether solvent and/or an ester solvent whose water solubility at 25° C. is 1 weight % or less in the solvent, with a concentration of 10 weight % or higher in the compositions.

### BACKGROUND OF THE INVENTION

1. Field of the Invention

The present invention relates to compositions for an organic electroluminescent device and so on and more particularly, relates to compositions for the organic electroluminescent device used as coating solutions in a wet film forming method.

2. Description of the Related Art

In recent years, developments of electroluminescent devices (organic electroluminescent device) forming thin layers by organic materials instead of inorganic materials such as ZnS have been pursued and among them, improvements in luminous efficiency, enhancement of stability at the time of driving, and reduction in driving voltage have been actively studied. In particular, a cause of an increase in driving voltage is considered to be an insufficient contact between an anode and a hole transport layer and thus, means for improving the contact between the anode and the hole transport layer and reducing driving voltage by providing a hole injection layer between the anode and the hole transport layer has been studied.

Generally speaking, it is said that excellent advantages such as possible use of wider range of materials and enhancements in heat resistance and surface smoothness of a device can be achieved by forming a layer containing hole transport materials and an electron acceptor of the organic electroluminescent device with the wet film forming method when compared to a layer formation by a vacuum deposition method.

As such study examples of forming the hole injection layer of the organic electroluminescent device by the wet film forming method include: a method (refer to Patent document 1) of forming a hole injection/transport layer with a spin coating method using solutions of dichloromethane dissolving polyethers containing aromatic diamines and tris(4-bromophenyl)aminium hexachloro-antimonate (TBPAH), which are the hole transport materials and the electron acceptor, respectively; a method (refer to Patent document 2) of forming the hole injection layer with the spin coating method using solutions of 1,2-dichloroethane containing polyethers containing aromatic diamines; and a method (refer to Patent document 3) of forming the hole transport layer with the spin coating method using a solution of 1,2-dichloroethane containing a mixture of 4,4′-bis(N-m-tolyl-N-phenylamino)biphenyl and antimony pentachloride, which is the electron acceptor.

Patent document 1: Japanese Patent Laid-open Official Gazette No. 11-283750

Patent document 2: Japanese Patent Laid-open Official Gazette No. 2000-36390

Patent document 3: Japanese Patent Laid-open Official Gazette No. 2002-56985

Incidentally, 4,4′-bis(N-m-tolyl-N-phenylamino)biphenyl and polyethers containing aromatic diamines and so on used as materials for forming the hole injection layer and hole transport layer of the organic electroluminescent device, often have low solubility in solvents generally and thus, there is a problem that preparation of solutions with appropriate concentrations is difficult when forming the thin layers of organic materials by the wet film forming method.

On the other hand, affinity with a ground is important when forming the hole injection/transport layer with a high uniformity by the wet film forming method. Accordingly, solvents for the solutions used in the wet film forming method need to dissolve the hole injection/transport materials and also have a high affinity property with the ground at the same time. However, there is a problem that preparation of solutions satisfying these two requirements in balance is difficult.

Furthermore, drying rate of a coating solution is highly important in influencing an efficiency of manufacturing process when forming the organic electroluminescent device laminated with a plurality of layers by the wet film forming method. For example, when drying rate of the solvent of the coating solution applied by the spin coating method is too high, film formation of a uniform organic layer is difficult whereas when the drying rate is too low, there is a problem that a long drying time is required until proceeding to a film forming process of a next layer.

Moreover, when a solvent with high vapor pressure is used in the case of an ink jet method for example, the solvent vaporizes at the time of injecting the coating solution from an injection nozzle to a coated surface and the nozzle tends to clog because of this and there is a problem that the formation of the organic layer with high uniformity becomes difficult.

On the other hand, the hole injection layer and the hole transport layer are provided in an upper layer of the anode of the organic electroluminescent device and play a role in transporting holes injected from the anode to a light emitting layer. As the hole injection/transport materials for forming the hole injection layer and the hole transport layer, materials need to have high injection efficiency of holes injected from the anode and also need to be capable of efficiently transporting the injected holes to the light emitting layer.

As described above, as materials for forming such a hole injection layer and hole transport layer of the organic electroluminescent device, those having partial structures of triarylamine and carbazole as a hole injection/transport site are often used such as 4,4′-bis(N-m-tolyl-N-phenylamino)biphenyl and polyethers containing aromatic diamines and so on. Moreover, since the hole injection layer is required to have a low hole injection barrier from an anode, the electron acceptors such as antimony pentachloride and TBPAH are often added together with the hole injection/transport materials.

However, there is a possible case where properties of these hole injection/transport materials and electron acceptors change due to charge transfer with other compounds contained in same layers formed in the organic electroluminescent device. When the properties of the hole injection/transport materials and electron acceptors change, there is a problem that a hole injection/transport property of a layer formed by these materials and so on is reduced.

In addition, materials which readily deteriorate are used like aluminum and so on used as a cathode of the organic electroluminescent device. There is a problem that a performance as a light emitting device tends to reduce.

Furthermore, as described earlier, there is a possible case where the hole injection/transport materials and electron acceptors change their properties due to the charge transfer with other compounds. Accordingly, there is a problem that there is a tendency where impurities are formed readily in a coating solution prepared by the wet film forming method and storage stability of the coating solution is low.

The present invention is made to solve such problems of low solubility of the hole injection/transport materials and so on, low affinity with the ground, and drying characteristics of the coating solution, which have become apparent at the time of forming the hole injection/transport materials of the organic electroluminescent device by the wet film forming method.

In other words, an object of the present invention is to provide compositions for the organic electroluminescent device satisfying at least one of the following points as the coating solution used at the time of forming the hole injection layer and hole transport layer of the organic electroluminescent device by the wet film forming method. The points to be satisfied are improvements in solubility of the hole injection/transport materials, improvements in the affinity with a ground layer, or a possession of an appropriate drying rate for forming a uniform coated layer.

Moreover, another object of the present invention is to provide the organic electroluminescent device.

Furthermore, yet another object of the present invention is to provide favorable compositions for the organic electroluminescent device for forming the hole injection/transport layer by the wet film forming method without changing properties of the hole injection/transport materials and/or electron acceptors.

### SUMMARY OF THE INVENTION

In order to solve such problems, the coating solution favorably used in the wet film forming method is prepared using good solvents for the hole injection/transport materials.

In other words, according to the present invention, compositions for the organic electroluminescent device containing the hole injection/transport materials and/or the electron acceptor forming at least one layer out of the hole injection layer and hole transport layer of the organic electroluminescent device, a solvent dissolving these hole injection/transport materials and/or the electron acceptor, and characterized by containing at least one out of (1) an ether solvent and/or an ester solvent and (2) a solvent selected from solvents with a water solubility of 1 weight % or less at 25° C., with a concentration of 10 weight % or more in the composition, in this solvent can be provided.

In the compositions for the organic electroluminescent device where the present invention is applied, (1) an ether solvent and/or an ester solvent contained in the solvent dissolving the hole injection/transport materials and/or the electron acceptor, is favorably a solvent with a water solubility of 1 weight % or less at 25° C.

Moreover, in the compositions for the organic electroluminescent device where the present invention is applied, the solvent of (1) or (2) contained in the solvent dissolving the hole injection/transport materials and/or the electron acceptor, is favorably the solvent satisfying at least one of the conditions (3) to (5) described below.

(3) a solvent whose surface tension is lower than 40 mN/m at 20° C. (4) a solvent whose vapor pressure is 10 mmHg or lower at 25° C. (5) a mixed solvent of a solvent whose vapor pressure is 2 mmHg or higher at 25° C. with a solvent whose vapor pressure is lower than 2 mmHg at 25° C.

In the compositions for the organic electroluminescent device where the present invention is applied, when it is characterized by containing the ether solvent and/or the ester solvent in the solvent dissolving the hole injection/transport materials and/or the electron acceptor, concentrations of the hole injection/transport materials in the coating solution used in the wet film forming method can be increased, and a solution with the most appropriate concentration or viscosity can be prepared.

In the compositions for the organic electroluminescent device where the present invention is applied, when it is characterized by containing a solvent whose surface tension is lower than 40 mN/m at 20° C. in the solvent dissolving the hole injection/transport materials and/or the electron acceptor, the affinity between the coating solution and the ground used in the wet film forming method can be enhanced and the formation of the hole injection layer or the hole transport layer with a high uniformity of film quality is possible.

Moreover, in the compositions for the organic electroluminescent device where the present invention is applied, when it is characterized by containing solvents whose vapor pressure is 10 mmHg or lower at 25° C. in the solvent dissolving the hole injection/transport materials and/or the electron acceptor, the preparation of the coating solution with a satisfactory balance of drying rate in a film forming process in the wet film forming method is possible.

Furthermore, in the compositions for the organic electroluminescent device where the present invention is applied, when it is characterized by containing a mixed solvent of a solvent whose vapor pressure is 2 mmHg or higher at 25° C. with a solvent whose vapor pressure is lower than 2 mmHg at 25° C. in the solvent dissolving the hole injection/transport materials and/or the electron acceptor, uniformity of the hole injection layer or the hole transport layer of the organic electroluminescent device can be enhanced further by the wet film forming method.

In the compositions for the organic electroluminescent device where the present invention is applied, it is favorable to use aromatic amine compounds as the hole injection/transport materials and to use aromatic boron compounds as the electron acceptor.

Moreover, there is a case where aluminum and so on used as the cathode of the organic electroluminescent device, readily deteriorate due to impurities or water content. Accordingly, in the compositions for the organic electroluminescent device where the present invention is applied, when it is characterized by an amount of water content in the compositions containing the hole injection/transport materials and/or the electron acceptor and the solvent dissolving these is 1 weight % or less, deterioration of the organic electroluminescent device, in particular, of the cathode can be prevented.

Furthermore, the compositions for the organic electroluminescent device where the present invention is applied can be used as the coating solution for forming at least one layer out of the hole injection layer and the hole transport layer by the wet film forming method in the organic electroluminescent device in which at least the anode, hole injection layer, hole transport layer, light emitting layer, and cathode are laminated on its substrate.

Moreover, in the present invention, amounts of impurities contained in the coating solution used in the wet film forming method are reduced in an attempt to stabilize the hole injection/transport materials. In other words, the compositions for the organic electroluminescent device where the present invention is applied are compositions containing the hole injection/transport materials and/or the electron acceptor forming at least one layer out of the hole injection layer and hole injection/transport layer of the organic electroluminescent device, the solvent dissolving these hole injection/transport materials and/or the electron acceptor, and characterized by containing a quencher deactivating the hole injection/transport materials and/or the electron acceptor or a compound generating the quencher with a concentration of 1 weight % or lower in these compositions.

In the compositions for the organic electroluminescent device where the present invention is applied, when it is characterized by making a concentration of alcohol solvents, aldehyde solvents, or ketone solvents, which may act as the quencher in the composition or compounds generating the quencher, 1 weight % or lower, it is possible to reduce deactivation of cation radicals of the hole injection/transport materials generated from mixture of the hole injection/transport materials and/or the electron acceptor contained in the composition.

Moreover, in the compositions for the organic electroluminescent device where the present invention is applied, when it is characterized by making a concentration of protonic acid or halogen-based solvent, which can be quencher in the composition or a compound generating the quencher, 1 weight % or lower, it is possible to prevent change in properties of a hole injection transport site in the hole injection/transport materials contained in the compositions and to alleviate reduction in the hole injection/transport property of a layer obtained by the wet film forming method.

As described earlier, since solvents of alcohols, aldehydes, and ketones and solvents of protonic acid and halogens are unfavorable even when only one type is present and even more unfavorable when both types are present, it is favorable that concentration of each type is 1 weight % or lower and moreover, it is more favorable that the concentration of these solvents is 1 weight % or lower in total.

In the compositions for the organic electroluminescent device where the present invention is applied, it is favorable to use aromatic amine compounds as the hole injection/transport materials and to use aromatic boron compounds as the electron acceptor.

According to the present invention, the compositions for the organic electroluminescent device with improved solubility of the hole injection/transport materials and which are appropriate for forming the hole injection/transport layer by the wet film forming method will be provided.

### BRIEF DESCRIPTION OF THE DRAWINGS

FIGS. 1A to 1C are diagrams describing an organic electroluminescent device with thin layers formed by the wet film forming method using compositions for organic electroluminescent device where the present embodiments are applied.

### DETAILED DESCRIPTION OF PREFERRED EMBODIMENTS

Preferred embodiments (hereinafter referred to as the embodiments of the invention) for carrying out the present invention will be described in detail below. Note here that the present invention is not limited to the embodiments described below and can be executed in various forms within an outline thereof.

Compositions for an organic electroluminescent device where the present embodiments are applied are used as the coating solution when forming a hole injection layer and/or a hole transport layer provided between an anode and a light emitting layer by a wet film forming method in the organic electroluminescent device having the light emitting layer held between the anode and cathode.

It should be noted here that when there is only one layer between the anode and light emitting layer in the organic electroluminescent device, this layer will be called as the “hole injection layer” and when there are more than two layers, the one contacting the anode will be called as the “hole injection layer” and other layers will be collectively called as the “hole transport layer”. Additionally, there is a case where layers provided between the anode and light emitting layer will be collectively called as a “hole injection/transport layer”.

The compositions for the organic electroluminescent device where the present embodiments are applied contain hole injection/transport materials and/or an electron acceptor forming at least one layer out of the hole injection layer and the hole transport layer of the organic electroluminescent device, and a solvent dissolving these hole injection/transport materials and/or the electron acceptor. Note here that the solvent dissolving the hole injection/transport materials and/or the electron acceptor is a solvent usually dissolving the hole injection/transport materials and/or the electron acceptor of 0.05 weight % or more, favorably 0.5 weight % or more, and more favorably 1 weight % or more. Incidentally, halogenated solvents, especially chlorinated solvents are not favorable due to problems in handling and so on.

The solvent contained in the compositions for the organic electroluminescent device where the present embodiments are applied contains (1) an ether solvent and/or an ester solvent or (2) a solvent with a water concentration of 1 weight % or lower at 25° C. Concentration of these solvents (1) or (2) in the organic electroluminescent device is usually 10 weight % or higher, favorably 50 weight % or higher, and more favorably 80 weight % or higher.

Specific examples of (1) the ether solvent and ester solvent, which are contained in the solvent contained in the compositions for the organic electroluminescent device, where the present embodiments are applied, include aliphatic ethers such as ethylene glycol dimethyl ether, ethylene glycol diethyl ether, propylene glycol-1-monomethyl ether acetate (PGMEA); and aromatic ethers such as 1,2-dimethoxybenzene, 1,3-dimethoxybenzene, anisole, phenetole, 2-methoxytoluene, 3-methoxytoluene, 4-methoxytoluene, 2,3-dimethyl anisole, 2,4-dimethyl anisole, trifluoromethoxy anisole, pentafluoromethoxybenzene, 3-(trifluoromethyl)anisole, as ether solvents. As ester solvents, examples include aliphatic esters such as ethyl acetate, n-butyl acetate, ethyl lactate, and n-butyl lactate; and aromatic esters such as phenyl acetate, phenyl propionate, methyl benzoate, ethyl benzoate, isopropyl benzoate, propyl benzoate, n-butyl benzoate, 2-phenoxyethyl acetate, and ethyl (pentafluorobenzoate).

Specific examples of (2) the solvents with the water concentrations of 1 weight % or lower at 25° C. contained in the solvent contained in the compositions for the organic electroluminescent device where the present embodiments are applied include toluene, xylene, and mesitylene.

Among these (1) ether solvents or ester solvents, solvents with a water solubility of 1 weight % or less are favorable and those with the solubility of 0.6 weight % or less are more favorable and those with the solubility of 0.3 weight % or less are even more favorable and those with the solubility of 0.1 weight % or less at 25° C. are especially favorable.

Examples of solvents contained in the compositions for the organic electroluminescent device where the present embodiments are applied include (3) those with a surface tension less than 40 mN/m, favorably those with a surface tension of 36 mN/m or lower, and more favorably those with a surface tension of 33 mN/m or lower at 20° C. An affinity with a ground is important when forming a layer containing the hole injection/transport materials and/or the electron acceptor by the wet film forming method. In particular, in a case of the hole injection layer, since uniformity of film quality greatly influences uniformity and stability of light emission of the organic electroluminescent device, low surface tension is required for the coating solution used in the wet film forming method in order to form a uniform coating film with a higher leveling property. By using such solvents, it is possible to form uniform layers containing the hole injection/transport materials and/or the electron acceptor.

Specific examples include the aforementioned ether solvents and ester solvents. Concentrations of these solvents in the compositions are usually more than 10 weight % or higher, favorably 30 weight % or higher, and more favorably 50 weight % or higher.

Examples of solvents contained in the compositions for the organic electroluminescent device where the present embodiments are applied include (4) solvents whose vapor pressure at 25° C. is 10 mmHg or lower and favorably 5 mmHg or lower even though their usual vapor pressure at 25° C. is 0.1 mmHg or higher. By using such solvents, it is possible to prepare compositions suited for the manufacturing process of the organic electroluminescent device by the wet film forming method, and also appropriate for properties of the hole injection/transport materials and/or the electron acceptor. Specific examples include the aforementioned ether solvents and ester solvents and furthermore, those whose water solubility is 1 weight % or less at 25° C. Concentrations of these solvents in the compositions are usually 10 weight % or higher, favorably 30 weight % or higher, and more favorably 50 weight % or higher.

Examples of solvents contained in the compositions for the organic electroluminescent device where the present embodiments are applied include (5) a mixed solvent of a solvent whose vapor pressure at 25° C. is 2 mmHg or higher, favorably 3 mmHg or higher, and more favorably 4 mmHg or higher (note here that an upper limit is favorably 10 mmHg or lower) and a solvent whose vapor pressure at 25° C. is lower than 2 mmHg, favorably 1 mmHg or lower, and more favorably 0.5 mmHg or lower. By using such a mixed solvent, it is possible to form homogenous layers containing the hole injection/transport materials and/or the electron acceptor of the organic electroluminescent device by the wet film forming method. Concentration of such a mixed solvent is usually 10 weight % or higher, favorably 30 weight % or higher, and more favorably 50 weight % or higher.

Since the organic electroluminescent device is formed by laminating a number of layers formed of organic compounds, it is highly important that the film quality is uniform. When these layers are formed by the wet film forming method, known film forming methods such as coating methods like a spin coating method and a spray method, and printing methods like ink jet methods and screen methods can be adopted depending on materials thereof and properties of the ground. In particular, the spray method is effective in forming a uniform film onto an uneven surface. For example, the spray method is especially favorable in forming the layer from organic compounds on a surface where irregularities due to patterned electrodes or barriers between pixels remain. In a case of application by the spray method, droplets of the coating solution injected onto a coated surface from a nozzle are favorably as small as possible since the uniform film quality is achieved. A state is favorable where small droplets are formed immediately before attaching to a substrate by mixing the solvent with a high vapor pressure and volatilization of a part of the solvent from the droplets of the coating solution after the injection in a coating atmosphere. However, it has become clear due to the study by the present inventors and others that, in order to achieve more uniform film quality, ensuring time for leveling a liquid film formed on the substrate immediately after the application is needed and solvents drying more slowly, in other words, solvents with a low vapor pressure are also needed to be contained to some extent to achieve this object.

Specific examples of solvents whose vapor pressure ranges from 2 mmHg to 10 mmHg at 25° C. include anisole, cyclohexane, toluene, for example. Examples of solvents whose vapor pressure at 25° C. is lower than 2 mmHg include ethyl benzoate, methyl benzoate, tetralin, and phenetole.

As for proportion of the mixed solvent, the solvent whose vapor pressure at 25° C. is 2 mmHg or higher, is 5 weight % or more, favorably 25 weight % or more, and less than 50 weight % in a total amount of the mixed solvent and the solvent whose vapor pressure at 25° C. is lower than 2 mmHg, is 30 weight % or more, favorably 50 weight % or more, and especially favorably 75 weight % or more, and less than 95 weight % in the total amount of the mixed solvent.

Note that since the organic electroluminescent device is formed by laminating a number of layers formed from organic compounds, every layer needs to be a uniform layer. Since there is a concern that the water content is mixed in the coating film and deteriorating the uniformity of the film due to the mixing of water in a solution (composition) for the layer formation when the layer is formed by the wet film forming method, it is favorable that the amount of water content in the solution should be as small as possible. Specifically, the amount of water contained in the compositions for the organic electroluminescent device is favorably 1 weight % or less, more favorably 0.1 weight % or less, and even more favorably 0.05 weight % or less.

Moreover, since materials which are deteriorated markedly by water content in the cathode and so on are often used generally in the organic electroluminescent device, the presence of water content is not favorable also from a viewpoint of device deterioration. Methods for reducing the amount of water in the solution include use of a nitrogen gas seal or desiccants, dehydrating of solvents in advance, and use of solvents with low water solubility. In particular, when solvents with low water solubility are used, it is favorable since a phenomenon where a solution coating film bleaches by absorbing moisture in the air during a coating process can be prevented. From such a viewpoint, the compositions for the organic electroluminescent device where the present embodiments are applied favorably contain 10 weight % or more of the composition whose water solubility at 25° C. is 1 weight % or less (favorably 0.1 weight % or less), for example. Incidentally, it is more favorable that solvents satisfying the above described solubility conditions should be contained 30 weight % or more and especially favorably 50 weight % or more.

It should be noted that apart from the solvents described earlier, solvents contained in the compositions for the organic electroluminescent device where the present embodiments are applied can contain various other solvents where necessary. Examples of such other solvents include aromatic hydrocarbons such as benzene, toluene, and xylene; amides such as N,N-dimethylformamide and N,N-dimethylacetamide; and dimethylsulfoxide. Additionally, various additives such as leveling agents and antifoaming agents can also be contained.

As described earlier, the solvent in the compositions for the organic electroluminescent device where the present embodiments are applied contains (1) the ether solvent and/or the ester solvent or (2) the solvent whose water solubility at 25° C. is 1 weight % or less with a concentration of 10 weight % or higher in the compositions. Furthermore, the solvent of either (1) or (2) favorably satisfies any one of the conditions (3) to (5) described below. (3) the solvent whose surface tension is lower than 40 mN/m at 20° C. (4) the solvent whose vapor pressure is 10 mmHg or lower at 25° C. (5) the mixed solvent of the solvent whose vapor pressure is 2 mmHg or higher at 25° C. with the solvent whose vapor pressure is lower than 2 mmHg at 25° C.

Containing of at least one of the solvents selected from such solvents described in (1) to (5) with a predetermined concentration is effective in controlling various important properties such as adjustment of concentration or viscosity, affinity with the ground, and drying rate, in forming layers constituting the organic electroluminescent device.

Especially, in order to achieve an object of “forming the uniform hole injection/transport layer”, the compositions containing solvents satisfying as many conditions selected from (1) to (5) as possible are favorable.

The compositions for the organic electroluminescent device where the present embodiments are applied contain the hole injection/transport materials and/or the electron acceptor forming at least one layer out of the organic electroluminescent device and the solvent dissolving these hole injection/transport materials and/or the electron acceptor, and further characterized by containing the quencher deactivating the hole injection/transport materials and/or the electron acceptor contained in the compositions or compounds generating the quencher, whose concentration is 1 weight % or lower. Note here that the solvent dissolving the hole injection/transport materials and/or the electron acceptor is the solvent usually dissolving 0.05 weight % or more of the hole injection/transport materials and/or the electron acceptor, favorably 0.5 weight % or more, and even more favorably 1 weight % or more. Incidentally, the hole injection/transport materials and/or the electron acceptor will be described later.

Examples of the quencher deactivating the hole injection/transport materials and/or the electron acceptor or the compounds generating such a quencher contained in the compositions for the organic electroluminescent device where the present embodiments are applied, include alcohol solvents like ethyl alcohol; aldehyde solvents like benzaldehyde; ketone solvents such as methyl ethyl ketone, cyclohexanone, and acetophenone. Such alcohol solvents, aldehyde solvents, and ketone solvents readily react especially with the electron acceptor. Specifically, alcohols are oxidized to aldehydes or carboxylic acids and aldehydes are oxidized to carboxylic acids and ketones are subjected to condensation reactions among solvent molecules or form impurities by attaching to cation radicals of the hole injection/transport materials.

Accordingly, when a layer containing the hole injection/transport materials and/or the electron acceptor is formed by the wet film forming method, a solvent, which is readily oxidized, and the electron acceptor react due to presence of these in a solution. Moreover, the solvent, which is readily oxidized, can also react with cation radicals (this radical formation improves the hole injection/transport property) of the hole injection/transport materials formed from mixing of the hole injection/transport materials and the electron acceptor. Since impurities are formed due to consumption of the electron acceptor or the cation radicals in the coating solution by these reactions of the solvent, which is readily oxidized, the solution is gradually deactivated, resulting in reduction in storage stability of the solution, which is not favorable technically.

In addition, examples of the quencher deactivating the hole injection/transport materials and/or the electron acceptor or the compounds generating such a quencher include protonic acids and halogenated solvents. Specifically, protonic acids include inorganic acids such as hydrochloric acid and hydrobromic acid; and organic acids such as formic acid, acetic acid, and lactic acid. Examples of halogenated solvents include chlorinated solvents, solvents containing bromine, and solvents containing iodine.

In a case where the layer is formed by the wet film forming method using the solution containing the hole injection/transport materials and/or the electron acceptor, since organic acids react with the hole injection/transport sites, for example and transform them into ammonium salts when organic acids or halogenated solvents are contained in the solution, the hole injection/transport property of the obtained layer is reduced. Moreover, when halogenated solvents are contained, since these halogenated solvents are often mixed with acids corresponding to them and these acids transform the hole injection/transport sites similarly to organic acids described above, the hole injection/transport property of the obtained layer is again reduced. In addition, mixing of halogenated materials is not favorable due to their large environmental load.

The hole injection/transport materials and electron acceptor, which are components of the compositions for the organic electroluminescent device where the present embodiments are applied, will be described next. Examples of the hole injection/transport materials include aromatic amine compounds, phthalocyanine derivatives or porphyrin derivatives, metal complexes of 8-hydroxyquinoline derivatives having diaryl amino groups, and oligothiophene derivatives. Furthermore, macromolecular compounds having the hole transport sites in their molecules can also be used. Moreover, examples of the electron acceptor capable of oxidizing these hole injection/transport materials include one type of compound or two or more types of compounds selected from the group consisting of triaryl boron compounds, halogenated metals, Lewis acids, organic acids, salts formed of arylamines and halogenated metals, and salts formed of arylamines and Lewis acids.

Aromatic amine compounds as the hole injection/transport materials include compounds having triarylamine structures and can also be selected from compounds hitherto being used as materials for forming the hole injection/transport layer in the organic electroluminescent device where appropriate. Examples of aromatic amine compounds include binaphthyl compounds expressed by the general formula (1) below.

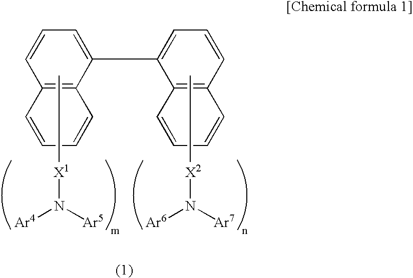

(In the general formula (1), symbols Ar⁴ to Ar⁷ each independently denote aromatic hydrocarbon ring of five or six-membered ring which may have substituent groups, or monocyclic group or fused ring group of aromatic heterocycle and pairs of Ar⁴ and Ar⁵, and Ar⁶ and Ar⁷, can also bond respectively to form rings. Letters m and n denote integers from 0 to 4 respectively and a relationship m+n≧1 is established. Symbols X¹ and X² each independently denote direct coupling or divalent linking group. Moreover, naphthalene rings in the general formula (1) may have arbitrary substituent groups in addition to groups —(X¹NAr⁴Ar⁵) and —(X²NAr⁶Ar⁷)).

In the general formula (1), symbols Ar⁴ to Ar⁷ denote aromatic hydrocarbon ring of five or six-membered ring which may have the substituent groups, or monocyclic group or fused ring group of aromatic heterocycle, for example, monocycles or 2 to 3 fused rings of five or six-membered rings and specific examples include aromatic hydrocarbon rings such as phenyl group, naphthyl group, and anthoryl group; and aromatic heterocycles such as pyridyl group and thienyl group. Any of these may have the substituent groups. Examples of the substituent groups, possibly contained in Ar⁴ to Ar⁷ include substituent groups described later as those possibly contained in Ar⁸ to Ar¹⁵ and arylamino groups (in other words, corresponding to groups —(NAr⁸Ar⁹), —(NAr¹⁰Ar¹¹) described later).

Additionally, pairs of Ar⁴ and Ar⁵ and/or Ar⁶ and Ar⁷ can also respectively bonded to form the rings. In this case, specific examples of rings formed include carbazole ring, phenoxazine ring, imino stilbene ring, phenothiazine ring, acridone ring, and imino dibenzyl ring which may respectively have substituent groups. Among them, carbazole ring is favorable.

In the general formula (1), letters m and n denote integers from 0 to 4 respectively and the relationship m+n≧1 is established. It is especially favorable when m=1 and also n=1. Note that when m and/or n are 2 or more, each arylamino group can be either same or different.

Symbols X¹ and X² each independently denote direct coupling or divalent linking group. Although there is no particular limit as the divalent linking groups, examples of such groups include those describe below. The direct coupling is particularly favorable as X¹ and X².

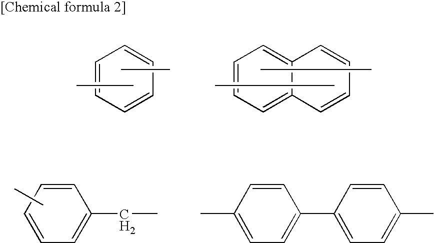

The naphthalene rings in the general formula (1) can have one arbitrary substituent group, or two or more at arbitrary positions in addition to groups —(X¹NAr⁴Ar⁵) and —(X²NAr⁶Ar⁷). Favorable groups of such substituent groups are one type or two or more types of substituent groups selected from the group consisting of alkyl groups possibly having halogen atoms, hydroxyl groups, and substituent groups, alkoxy groups possibly having substituent groups, alkenyl groups possibly having substituent groups, and alkoxy carbonyl group possibly having substituent groups. Among them, alkyl groups are particularly favorable.

As the binaphthyl compounds expressed by the general formula (1), binaphthyl compounds whose Ar⁴ and Ar⁶ are further substituted by arylamino groups respectively as expressed by the general formula (2) described below are favorable.

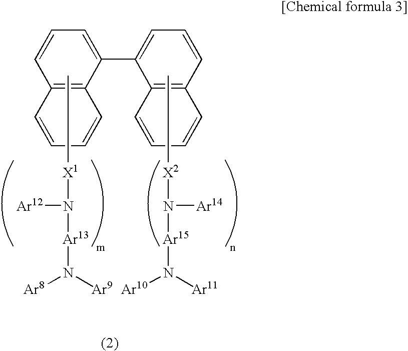

(In the general formula (2), symbols Ar⁸ to Ar¹⁵ each independently denote aromatic hydrocarbon rings of five or six-membered ring which may have substituent groups, or monocyclic group or fused ring group of aromatic heterocycle and pairs of Ar⁸ and Ar⁹, and Ar¹⁰ and Ar¹¹ can also bond respectively to form the rings. Letters m and n are synonymous with those in the general formula (1). Symbols X¹ and X² are synonymous with those in the general formula (1)).

The naphthalene rings in the general formula (2) may have arbitrary substituent groups, in addition to substituent groups —(X¹NAr¹²Ar¹³NAr⁹Ar⁸) and —(X²NAr¹⁴Ar¹⁵NAr⁹Ar¹¹) containing arylamino groups respectively bonded to the naphthalene rings. Moreover, these substituent groups —(X¹NAr¹²Ar¹³NAr⁹Ar⁸) and —(X²NAr¹⁴Ar¹⁵NAr¹⁰Ar¹¹) can be substituting at any substitution positions of the naphthalene rings. Among them, binaphthyl compounds substituted at positions 4- and 4′-respectively of the naphthalene rings in the general formula (2) are more favorable.

Similar to those compounds expressed by the general formula (1), binaphthylene structures in the compounds expressed by the general formula (2) also favorably have substituent groups at 2- and 2′-positions. Examples as the substituent groups bonded to 2-, 2′-positions include alkyl groups possibly having halogen atoms, hydroxyl groups, and substituent groups, alkoxy groups possibly having substituent groups, alkenyl groups possibly having substituent groups, and alkoxy carbonyl groups possibly having substituent groups. Note that the binaphthylene structures in the compounds expressed by the general formulae (1) and (2) can also have substituent groups at positions other than 2- and 2′-positions and examples as the substituent groups include each of those groups listed earlier as the substituent groups at 2- and 2′-positions. Molecular weight of the binaphthyl compounds expressed by the general formula (1) is usually lower than 2000, favorably lower than 1200 and usually 500 or higher and favorably 700 or higher.

Compounds expressed by a general formula (3) or (4) described below are also favorable as the aromatic amine compounds. Molecular weights of these compounds expressed by the general formula (3) or (4) are comparable to those expressed by the general formula (1) and favorable molecular weights are also comparable.

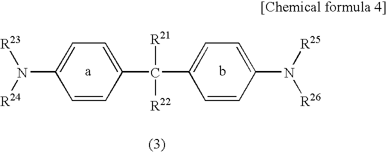

(In the general formula (3), symbols R²¹ and R²² each independently denote alkyl groups possibly having hydrogen atoms, hydroxyl groups, or substituent groups, alkenyl groups possibly having substituent groups, aromatic hydrocarbon groups possibly having substituent groups, heteroaromatic ring groups possibly having substituent groups, acenaphthyl groups possibly having substituent groups, and fluorenyl groups possibly having substituent groups. Moreover, R²¹ and R²² may also bond to form a non-aromatic ring possibly having substituent groups).

(Symbols R²³ to R²⁶ each independently denote aromatic hydrocarbon groups possibly having substituent groups, heteroaromatic ring groups possibly having substituent groups, acenaphthyl groups possibly having substituent groups, and fluorenyl groups possibly having substituent groups. Alternatively, pairs of R²³ and R²⁴, R²³ and carbon atoms constituting a ring a, R²⁴ and the carbon atoms constituting the ring a, R²⁵ and R²⁶, R²⁵ and carbon atoms constituting a ring b, or R²⁶ and the carbon atoms constituting the ring b may also bond to form rings possibly having substituent groups, respectively. Note that the rings a and b express benzene rings possibly having substituent groups).

In the general formula (3), specific examples of R²³ to R²⁶ include aromatic hydrocarbon groups of monocycles of six-membered rings or fused rings of 2 to 4 thereof such as phenyl groups, naphthyl groups, anthryl groups, pyrenyl groups, and phenanthyl groups; heteroaromatic ring groups of monocycles of 5 or 6 membered rings or fused rings of 2 to 4 thereof such as pyridyl groups, thienyl groups, pyrazyl groups, thiazolyl groups, phenanthridyl groups, quinolyl groups, and carbazolyl groups; fluorenyl groups and acenaphthyl groups.

It should be noted that pairs of R²³ and R²⁴, R²³ and the carbon atoms constituting the ring a, R²⁴ and the carbon atoms constituting the ring a, R²⁵ and R²⁶, R²⁵ and carbon atoms constituting the ring b, or R²⁶ and the carbon atoms constituting the ring b may also bond to form rings possibly having substituent groups.

Other than the groups described above as R²³ to R²⁶, hydrogen atoms, hydroxyl groups, linear, branched, or cyclic alkyl groups with 1 to 10 carbon atoms or linear, branched, or cyclic alkenyl groups with 2 to 11 carbon atoms may also be as R²¹ and R²². Moreover, R²¹ and R²² may also bond to form the non-aromatic ring possibly having substituent groups, and 5 or 6 membered rings such as cyclohexane rings, cyclopentane rings, cyclohexene rings and cyclopentene rings are favorable as the non-aromatic rings.

Examples of substituent groups possibly possessed by alkyl groups, alkenyl groups, aromatic hydrocarbon groups, heteroaromatic ring groups, acenaphthyl groups, fluorenyl groups, non-aromatic ring formed by bonding of R²¹ and R²², and rings formed by bonding of two or more groups selected from the group consisting of groups R²³ to R²⁶ and carbon atoms constituting the rings a and b, all of which may be R²¹ to R²⁶, include halogen atoms, alkyl groups, alkenyl groups, aromatic hydrocarbon groups, aralkyl gruops, dialkylamino groups, and diarylamino groups, although not limited to the above described substituent groups.

Furthermore, when at least one of the groups R²¹ to R²⁶ is the fused ring group formed by condensation of 3 or more aromatic rings (aromatic hydrocarbon rings or heteroaromatic rings), it is favorable since glass transition temperature (Tg) of compounds increases. Especially when at least one of the groups R²¹ to R²⁶ is phenanthryl groups possibly having substituent groups, it is favorable since a driving life of a device prepared by using this tends to increase.

Next, compounds expressed by the general formula (4) are as follows.

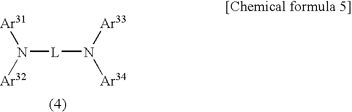

(In the general formula (4), symbols Ar³¹ to Ar³⁴ each independently denote aromatic hydrocarbon groups possibly having substituent groups, or heteroaromatic ring groups possibly having substituent groups and a letter L denotes any of divalent linking groups expressed below).
—Ar³⁵—, —Ar³⁶—Ar³⁷—, —Ar³⁸—Ar³⁹—Ar⁴⁰—, —Ar⁴¹—Ar⁴²—Ar⁴³—Ar⁴⁴—

(In the formula, symbols Ar³⁵ to Ar⁴⁴ each independently denote aromatic hydrocarbon rings of 5 or 6 members, which can be substituted, or divalent groups formed from monocycles of heteroaromatic rings or fused rings of 2 to 4 thereof).

In the general formula (4), symbols Ar³¹ to Ar³⁴ each independently denote aromatic hydrocarbon groups possibly having substituent groups, or heteroaromatic ring groups possibly having substituent groups. As the aromatic hydrocarbon groups and heteroaromatic ring groups, examples include groups similar to those described as examples of R²³ to R²⁶ in the general formula (3). The letter L denotes any of the divalent linking groups described below.
—Ar³⁵—, —Ar³⁶—Ar³⁷—, —Ar³⁸—Ar³⁹—Ar⁴⁰—, —Ar⁴¹—Ar⁴²—Ar⁴³—Ar⁴⁴—

Symbols Ar³⁵ to Ar⁴⁴ each independently denote aromatic hydrocarbon rings of 5 or 6 members, which may be substituted, or divalent groups formed from monocycles of heteroaromatic rings or fused rings of 2 to 4 thereof and specific examples of such groups include divalent groups formed by eliminating one hydrogen atom from the groups described as examples of R²³ to R²⁶ in the general formula (3).

Examples of substituent groups possibly possessed by the groups Ar³¹ to Ar⁴⁴ include halogen atoms, alkyl groups, aralkyl groups, alkenyl groups, cyano groups, dialkylamino groups, diaryl amino groups, arylalkyl amino groups, acyl groups, alkoxy carbonyl groups, carboxyl groups, alkoxy groups, aryloxy groups, alkyl sulfonyl groups, hydroxyl groups, amide groups, aromatic hydrocarbon ring groups, and heteroaromatic ring groups. Among them, halogen atoms, alkyl groups, alkoxy groups, aromatic hydrocarbon ring groups, and heteroaromatic ring groups are favorable.

Since aromatic amine compounds contained in the organic electroluminescent device where the present embodiments are applied are used for the layer formation by the wet film forming method, those readily dissolve in various solvents are favorable. For example, in a case of compounds expressed by the general formula (1), it is considered that solubility improves since two naphthalene rings are in a twisted configuration due to presence of substituent groups at 2- and 2′-positions. Moreover, in a case of compounds expressed by the general formula (3), it is considered that solubility in a solvent is improved since molecular structures may form non-conjugated structures in a methylene group moiety possibly having substituent groups, which are bonding the rings a and b. In a case of compounds expressed by the general formula (4), it is considered that solubility improves since molecular configuration is twisted by selecting any group out of —Ar³⁶—Ar³⁷—, —Ar³⁸—Ar³⁹—Ar⁴⁰—, —Ar⁴¹—Ar⁴²—Ar⁴³—Ar⁴⁴—, as the liking group L and by having substituent groups in specified positions. In other words, solubility improves since Ar³⁶ and Ar³⁷ are not being present on a same plane but in a twisted configuration due to possession of the substituent groups at an a-position to a bond between Ar³⁶ and Ar³⁷ in each of Ar³⁶ and Ar³⁷. The same applies to the pairs of Ar³⁸ and Ar³⁹, Ar³⁹ and Ar⁴⁰, Ar⁴¹ and Ar⁴², Ar⁴² and Ar⁴³, and Ar⁴³ and Ar⁴⁴.

Compounds hitherto known can be used as the hole injection/transport materials other than compounds expressed by the general formulae (1), (3), and (4). Such compounds hitherto known include aromatic diamine compounds linking a tertiary aromatic amine unit such as 1,1-bis(4-di-p-torylaminophenyl)cyclohexane (Japanese Patent Laid-open Official Gazette No. Sho 59-194393); aromatic amines containing two or more tertiary amines represented by 4,4′-bis[N-(1-naphthyl)-N-phenylamino]biphenyl where two or more fused aromatic rings are substituted by nitrogen atoms (Japanese Patent Laid-open Official Gazette No. Hei 05-234681); aromatic triamines, which are derivatives of triphenylbenzene, and having star burst structures (U.S. Pat. No. 4,923,774); aromatic diamines such as N,N′-diphenyl-N,N′-bis(3-methylphenyl)biphenyl-4,4′-diamine (U.S. Pat. No. 4,764,625); α,α,α′,α′-tetramethyl-α,α′-bis(4-di-p-tolylaminophenyl)-p-xylene (Japanese Patent Laid-open Official Gazette No. Hei 03-269084); triphenylamine derivatives, which are sterically asymmetric as molecules as a whole (Japanese Patent Laid-open Official Gazette No. Hei 04-129271), compounds whose pyrenyl groups are substituted by a plurality of aromatic diamine groups (Japanese Patent Laid-open Official Gazette No. Hei 04-175395); aromatic diamines linking a tertiary aromatic amine unit with an ethylene group (Japanese Patent Laid-open Official Gazette No. Hei 04-264189); aromatic diamines with styryl structures (Japanese Patent Laid-open Official Gazette No. Hei 04-290851); those linking a tertiary aromatic amine unit with a thiophene group (Japanese Patent Laid-open Official Gazette No. Hei 04-304466); aromatic triamines of a starburst type (Japanese Patent Laid-open Official Gazette No. Hei 04-308688); benzylphenyl compounds (Japanese Patent Laid-open Official Gazette No. Hei 04-364153); those linking tertiary amines with fluorene groups (Japanese Patent Laid-open Official Gazette No. Hei 05-25473); triamine compounds (Japanese Patent Laid-open Official Gazette No. Hei 05-239455); bisdipyridylaminobiphenyl (Japanese Patent Laid-open Official Gazette No. Hei 05-320634); N,N,N-triphenylamine derivatives (Japanese Patent Laid-open Official Gazette No. Hei 06-1972); aromatic diamines with phenoxazine structures (Japanese Patent Laid-open Official Gazette No. Hei 07-138562); diaminophenyl phenantolidine derivatives (Japanese Patent Laid-open Official Gazette No. Hei 07-252474); hydrazone compounds (Japanese Patent Laid-open Official Gazette No. Hei 02-311591); silazane compounds (US Patent Official Gazette U.S. Pat. No. 4,950,950); silanamine derivatives (Japanese Patent Laid-open Official Gazette No. Hei 06-49079); phosphamine derivatives (Japanese Patent Laid-open Official Gazette No. Hei 06-25659); and quinacridone compounds. These compounds can be used singly or by mixing two or more kinds where necessary.

Specific examples of favorable phthalocyanine derivatives or porphyrin derivatives used as the hole injection/transport materials include compounds described below such as porphyrin, 5,10,15,20-tetraphenyl-21H,23H-porphyrin, cobalt (II) 5,10,15,20-tetraphenyl-21H,23H-porphyrin, copper (II) 5,10,15,20-tetraphenyl-21H,23H-porphyrin, zinc (II) 5,10,15,20-tetraphenyl-21H,23H-porphyrin, 5,10,15,20-tetraphenyl-21H,23H-porphyrin vanadium (IV) oxide, 5,10,15,20-tetra(4-pyridyl)-21H,23H-porphyrin, 29H,31H-phthalocyanine copper (II), phthalocyanine zinc (II), phthalocyanine titanium, phthalocyanine oxide magnesium, phthalocyanine lead, phthalocyanine copper (II), 4,4′,4″,4′″-tetraaza-29H, 31H-phthalocyanine, magnesium oxide phthalocyanine.

Furthermore, examples of metal complexes of 8-hydroxyquinoline derivatives with diarylamino groups used as the hole injection/transport materials include those expressed by the general formula (5) described below.

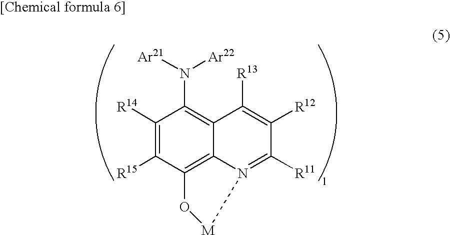

In the general formula (5), symbols Ar²l and Ar²² each independently denote aromatic groups possibly having substituent groups, or heteroaromatic ring groups possibly having substituent groups. Symbols R¹¹ to R¹⁵ each independently denote hydrogen atoms, halogen atoms, alkyl groups, aralkyl groups, alkenyl groups, alkynyl groups, cyano groups, amino groups, amide groups, nitro groups, acyl groups, alkoxy carbonyl groups, carboxyl groups, alkoxy groups, alkyl sulfonyl groups, hydroxyl groups, aromatic hydrocarbon groups or heteroaromatic ring groups.

Note that the pairs of R¹¹ and R¹², R¹² and R¹³, or R¹⁴ and R¹⁵ may also form rings and moreover, when any of R¹¹ to R¹⁵ is denoting alkyl groups, aralkyl groups, alkenyl groups, alkynyl groups, secondary or tertiary amino groups, amide groups, acyl groups, alkoxy carbonyl groups, alkoxy groups, alkyl sulfonyl groups, aromatic hydrocarbon groups or heteroaromatic ring groups, this group may have substituent groups at its hydrocarbon moiety.

Moreover, the letter M denotes an alkaline metal, alkaline earth metal, Sc, Y, V, Cr, Mn, Fe, Co, Ni, Cu, Zn, Cd, Al, Ga, In, Si, Ge, Sn, Sm, Eu, or Tb and the letter 1 represents an integer from 2 to 4.

Specific examples of compounds expressed by the general formula (5) include those as follows.

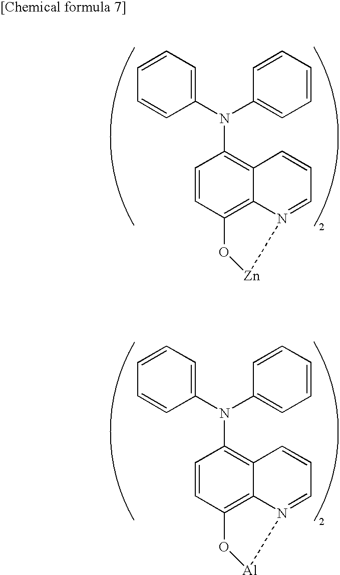

Examples of oligothiophene derivatives used as the hole injection/transport materials include α-sexythiophene. Note that molecular weights of these hole injection/transport materials are usually lower than 2000, favorably lower than 1800, and more favorably lower than 1200 although usually 500 or higher and favorably 700 or higher.

Moreover, examples of polymer compounds having hole transport site in molecules and being used as the hole injection/transport materials include polymer compounds containing aromatic tertiary amino groups as building blocks in main skeletons. Specific examples include the hole injection/transport materials with the structures expressed by the general formulae (II) and (III) below as repeating units.

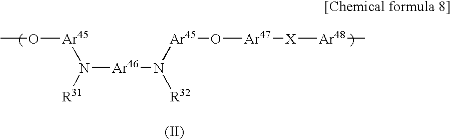

(In the formula (II), symbols Ar⁴⁵ to Ar⁴⁸ each independently denote divalent aromatic ring groups possibly having substituent groups, symbols R³¹ to R³² denote monovalent aromatic ring groups possibly having substituent groups, and X is a direct coupling or is selected from linking groups described below. Note that a term “aromatic ring group” includes both “a group originated from aromatic hydrocarbon rings” and “a group originated from heteroaromatic rings”).

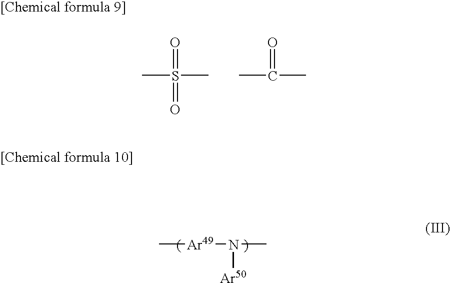

(In the formula (III), a symbol Ar⁴⁹ represents a divalent aromatic ring group possibly having substituent groups and a symbol Ar⁵⁰ represents a monovalent aromatic ring group possibly having substituent groups).

In the general formula (II), symbols Ar⁴⁵ to Ar⁴⁸ each independently favorably denote divalent benzene rings, naphthalene rings, anthracene rings, or biphenyl groups, possibly having substituent groups, and more favorably benzene rings. Examples of the aforementioned substituent groups include halogen atoms; linear or branched alkyl groups with 1 to 6 carbon atoms such as methyl group and ethyl group; alkenyl groups such as vinyl group; linear or branched alkoxy carbonyl groups with 2 to 7 carbon atoms such as methoxy carbonyl group and ethoxy carbonyl group; linear or branched alkoxy groups with 1 to 6 carbon atoms such as methoxy groups and ethoxy groups; aryloxy groups with 6 to 12 carbon atoms such as phenoxy groups and benzyloxy groups; dialkylamino groups having alkyl chains with 1 to 6 carbon atoms such as diethylamino groups and diisopropylamino groups. Among them, alkyl groups with 1 to 3 carbon atoms are favorable and methyl groups are especially favorable. A case where every Ar⁴⁵ to Ar⁴⁸ is non-substituted aromatic ring group is most favorable.

Groups such as phenyl groups, naphthyl groups, anthryl groups, pyridyl groups, triazyl groups, pyrazyl groups, quinoxalyl groups, thienyl groups, or biphenyl groups each independently possibly having substituent groups are favorable as R³¹ and R³² and more favorably phenyl groups, naphthyl groups, or biphenyl groups and most favorably phenyl groups. Examples of substituent groups possibly possessed by aromatic rings in Ar⁴⁵ to Ar⁴⁸ include similar groups to those mentioned earlier.

Compounds with the structure expressed by the general formula (II) as the repeating unit are synthesized via a pathway disclosed in a method by Kido and others (Polymers for Advanced Technologies, vol. 7, p. 31, 1996; Japanese Patent Laid-open Official Gazette No. Hei 09-188756), for example.

In the general formula (III), a symbol Ar⁴⁹ represents divalent aromatic ring groups possibly having substituent groups, and favorably aromatic hydrocarbon ring groups from a viewpoint of a hole transport property, and specific examples thereof include benzene rings, naphthalene rings, anthracene rings, biphenyl groups, and terphenyl groups, which are divalent and possibly having subsituent groups. Moreover, examples of substituent groups possibly possessed by aromatic rings in Ar⁴⁵ to Ar⁴⁸ include similar groups to those mentioned earlier. Among them, alkyl groups with 1 to 3 carbon atoms are favorable and methyl groups are especially favorable.

A symbol Ar⁵⁰ represents an aromatic ring group possibly having substituent groups, and favorably an aromatic hydrocarbon ring group from a viewpoint of the hole transporting property, and specific examples thereof include phenyl groups, naphthyl groups, anthryl groups, pyridyl groups, triazyl groups, pyrazyl groups, quinoxalyl groups, thienyl groups, or biphenyl groups possibly having substituent groups. Examples of substituent groups possibly possessed by aromatic rings in Ar⁴⁵ to Ar⁴⁸ include similar groups to those mentioned earlier.

A case where both Ar⁴⁹ and Ar⁵⁰ are non-substituted aromatic ring groups is most favorable in compounds expressed by the general formula (III). Compounds with the structures expressed by the general formula (III) as repeating units can be synthesized by reacting materials described below at 110° C. for 16 hours in organic solvents like xylene under the presence of palladium catalyst in accordance with materials and a reaction formula below, for example.

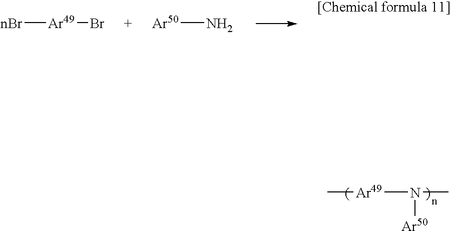

Examples of the hole injection/transport materials containing aromatic tertiary amino groups as side chains include compounds with structures expressed by the general formulae (IV) and (V) as repeating units.

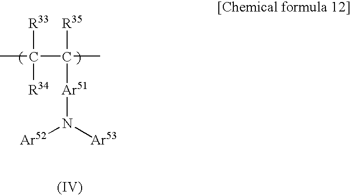

(In the formula, a symbol Ar⁵¹ represents a divalent aromatic ring group possibly having substituent groups, and symbols Ar⁵² to Ar⁵³ represent monovalent aromatic ring groups possibly having substituent groups, and symbols R³³ to R³⁵ each independently denote monovalent aromatic ring groups possibly having hydrogen atoms, halogen atoms, alkyl groups, alkoxy groups or substituent groups.

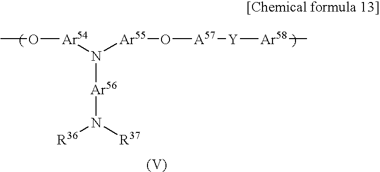

(In the formula, symbols Ar⁵⁴ to Ar⁵⁸ each independently denote divalent aromatic ring groups possibly having substituent groups, symbols R³⁶ and R³⁷ represent aromatic ring groups possibly having substituent groups, and Y is a direct coupling or is selected from linking groups described below.

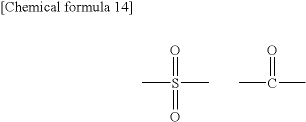

In the general formula (IV), a symbol Ar⁵¹ represents favorably divalent benzene ring, naphthalene ring, anthracene ring, or biphenyl groups, each possibly having substituent groups, and examples of the substituent groups include groups similar to those mentioned earlier as the groups possibly possessed by aromatic rings in Ar⁴⁵ to Ar⁴⁸ in the aforementioned general formula (II) and favorable groups are also similar. Favorable groups as Ar⁵² and Ar⁵³ each independently include phenyl groups, naphthyl groups, anthryl groups, pyridyl groups, triazyl groups, pyrazyl groups, quinoxalyl groups, thienyl groups, or biphenyl groups, which possibly have substituent groups. Examples of the substituent groups include groups similar to those mentioned earlier as the groups possibly possessed by aromatic rings in Ar⁴⁵ to Ar⁴⁸ in the general formula (II) and favorable groups are also similar.

Symbols R³³ to R³⁵ are favorably each independently denote hydrogen atoms; halogen atoms; linear or branched alkyl groups with 1 to 6 carbon atoms such as methyl groups and ethyl groups; linear or branched alkoxy groups with 1 to 6 carbon atoms such as methoxy groups and ethoxy groups; phenyl groups; or thryl groups. Compounds having the structures expressed by the general formula (IV) as repeating units are synthesized via a pathway disclosed in Japanese Patent Laid-open Official Gazette No. Hei 01-105954, for example.

In the general formula (V), symbols Ar⁵⁴ to Ar⁵⁸ each independently favorably denote divalent benzene rings, naphthalene rings, anthracene rings, or biphenyl groups, possibly having substituent groups, and more favorably benzene ring. Examples of the substituent groups include groups similar to those mentioned earlier as the groups possibly possessed by the aromatic rings in Ar⁴⁵ to Ar⁴⁵ in the general formula (II) and favorable groups are also similar.

Symbols R³⁶ and R³⁷ favorably each independently denote phenyl groups, naphthyl groups, anthryl groups, pyridyl groups, triazyl groups, pyrazyl groups, quinoxalyl groups, thienyl groups, or biphenyl groups possibly having substituent groups. Examples of the substituent groups include groups similar to those mentioned earlier as the groups possibly possessed by the aromatic rings in Ar⁴⁵ to Ar⁴⁸ in the general formula (II) and favorable groups are also similar. Compounds expressed by the general formula (V) are synthesized via the pathway disclosed in the method by Kido and others (Polymers for Advanced Technologies, vol. 7, p 31, 1996; Japanese Patent Laid-open Official Gazette No. Hei 09-188756), for example.

Although favorable examples of the structures shown in the general formulae (II) to (V) are shown below, the structures are not limited to these.

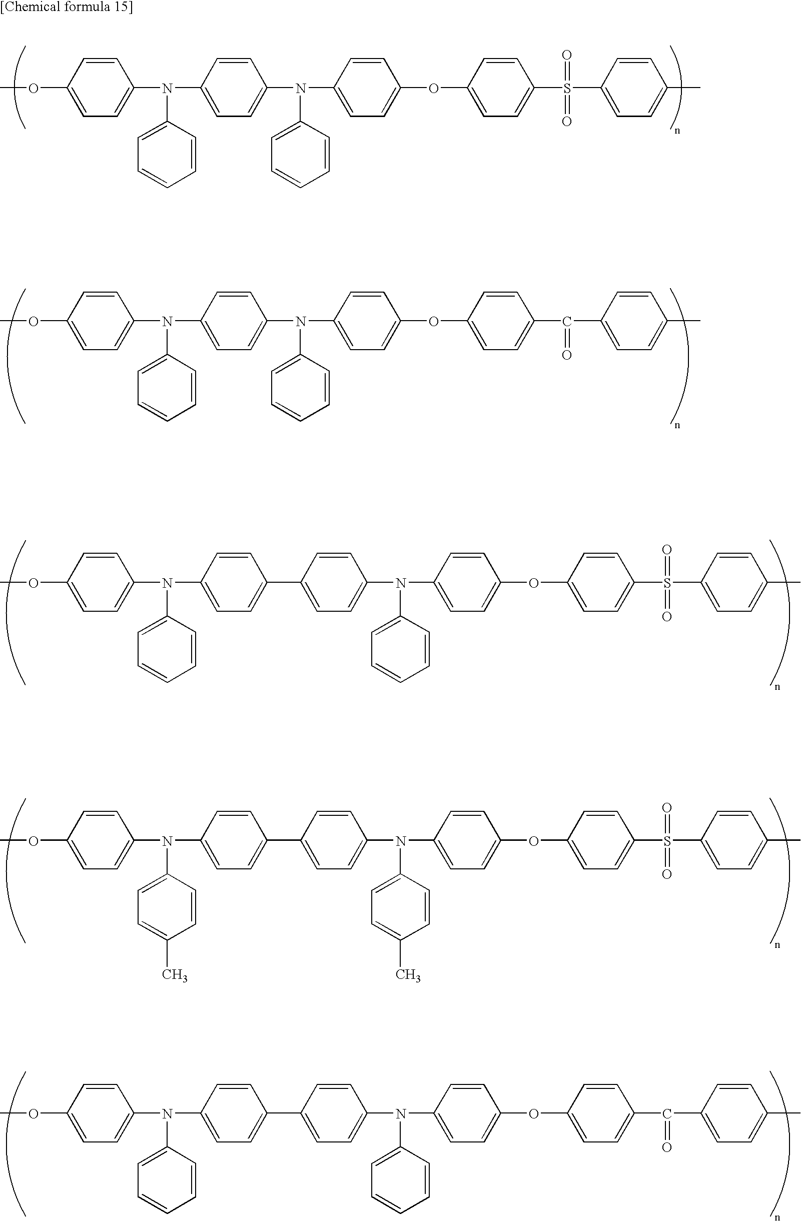

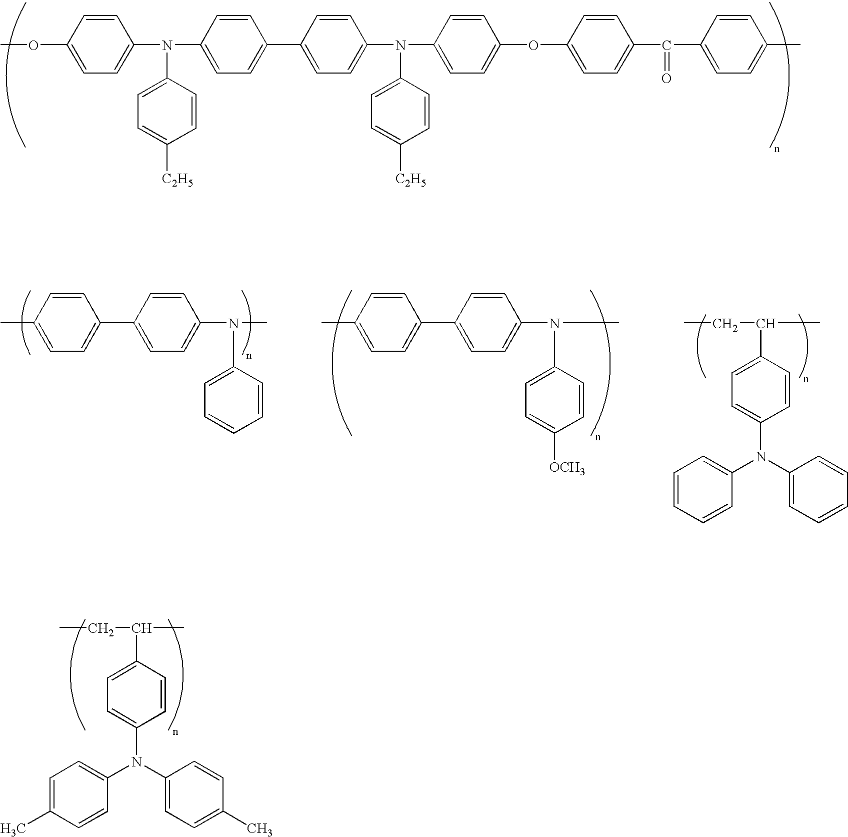

Although the hole injection/transport materials, which are polymer compounds having hole transport sites in molecules, are most favorably homopolymers with structures expressed by any of the general formulae (II) to (V), the materials may also be copolymers with another arbitrary monomer. When the materials are copolymers, they contain building blocks expressed by the general formulae (II) to (V) favorably 50 mol % or more and especially favorably 70 mol % or more. Note that the hole injection/transport materials, which are polymer compounds, may also contain plural kinds of the structures expressed by the general formulae (II) to (V) in one compound. Moreover, plural kinds of compounds containing the structures expressed by the general formulae (II) to (V) may also be used in combination. Homopolymers are especially favorable when formed of the repeating units expressed by the general formula (II) among those expressed by the general formulae (II) to (V). Conjugated polymers may further be included as the hole injection/transport materials formed from polymer compounds. Polyfluorene, polypyrrole, polyaniline, polythiophene, and polypara-phenylene vinylene are suited for this purpose.

Furthermore, examples of polymer compounds having the hole transport sites in molecules and used as the hole injection/transport materials include polyethers containing aromatic diamines (Japanese Patent Laid-open Official Gazette No. 2000-36390); polyvinylcarbazole, polysilane, polyphosphazene, (Japanese Patent Laid-open Official Gazette No. Hei 05-310949); polyamides (Japanese Patent Laid-open Official Gazette No. Hei 05-310949); polyvinyltriphenylamines (Japanese Patent Laid-open Official Gazette No. Hei 07-53953); polymers with triphenylamine skeletons (Japanese Patent Laid-open Official Gazette No. Hei 04-133065); and poly(meth)acrylates containing aromatic amines.

The electron acceptor will be described next. Examples of the electron acceptor contained in the compositions for the organic electroluminescent device where the present embodiments are applied include one type of compound or two or more thereof selected from the group consisting of triaryl boron compounds, halogenated metals, Lewis acids, organic acids, salts of arylamines and halogenated metals, and salts of arylamines and Lewis acids. These electron acceptors are used by mixing with the hole injection/transport materials and capable of improving conductivity of the hole injection layer by oxidizing the hole injection/transport materials.

Examples of triaryl boron compounds adopted as the electron acceptors include boron compounds shown in the general formula (6) described below. The boron compounds expressed by the general formula (6) are favorably Lewis acids. Moreover, electron affinity of the boron compounds are usually 4 eV or higher and favorably 5 eV or higher.

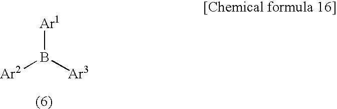

In the general formula (6), symbols Ar¹ to Ar³ each independently denote monocycles of five or six-membered ring, which may have substituent groups or aromatic hydrocarbon ring groups formed by fusing and/or directly coupling 2 to 3 thereof, such as phenyl groups, naphthyl groups, anthryl groups, and biphenyl groups; or monocycles of five or six-membered ring, which may have substituent groups or heteroaromatic ring groups formed by fusing and/or directly coupling 2 to 3 thereof, such as thienyl groups, pyridyl groups, triazyl groups, pyrazyl groups, and quinoxalyl groups, possibly having subtituent groups.

Examples of such substituent groups include halogen atoms such as fluorine atoms; linear or branched alkyl groups with 1 to 6 carbon atoms, such as methyl groups and ethyl groups; alkenyl groups such as vinyl groups; linear or branched alkoxy carbonyl groups with 1 to 6 carbon atoms such as methoxy carbonyl group and ethoxy carbonyl group; linear or branched alkoxy groups with 1 to 6 carbon atoms, such as methoxy group and ethoxy group; aryloxy groups such as phenoxy groups and benzyloxy groups; dialkylamino groups such as dimethylamino groups and diethylamino groups; acyl groups such as acetyl groups, haloalkyl groups such as trifluoromethyl groups, and cyano groups.

Compounds having such substituent groups where at least one of Ar¹ to Ar³ exhibits a positive Hammett constant (σₘ and/or σₚ) are favorable and compounds having such substituent groups where every Ar¹ to Ar³ exhibits positive Hammett constant (σₘ and/or σₚ) are especially favorable. Electron accepting properties of these compounds improve by having substituent groups with such electron withdrawing properties. Additionally, compounds where every Ar¹ to Ar³ expresses aromatic hydrocarbon groups or heteroaromatic ring groups substituted by halogen atoms are even more favorable.

Although specific examples (1 to 30) of favorable boron compounds expressed by the general formula (6) are shown below, the compounds are not limited to these.

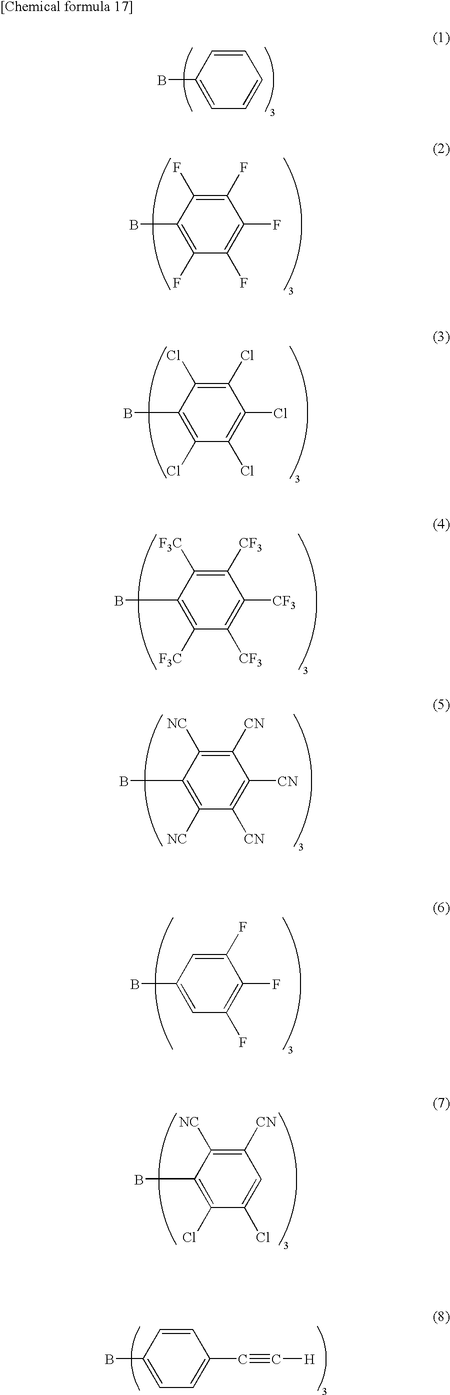

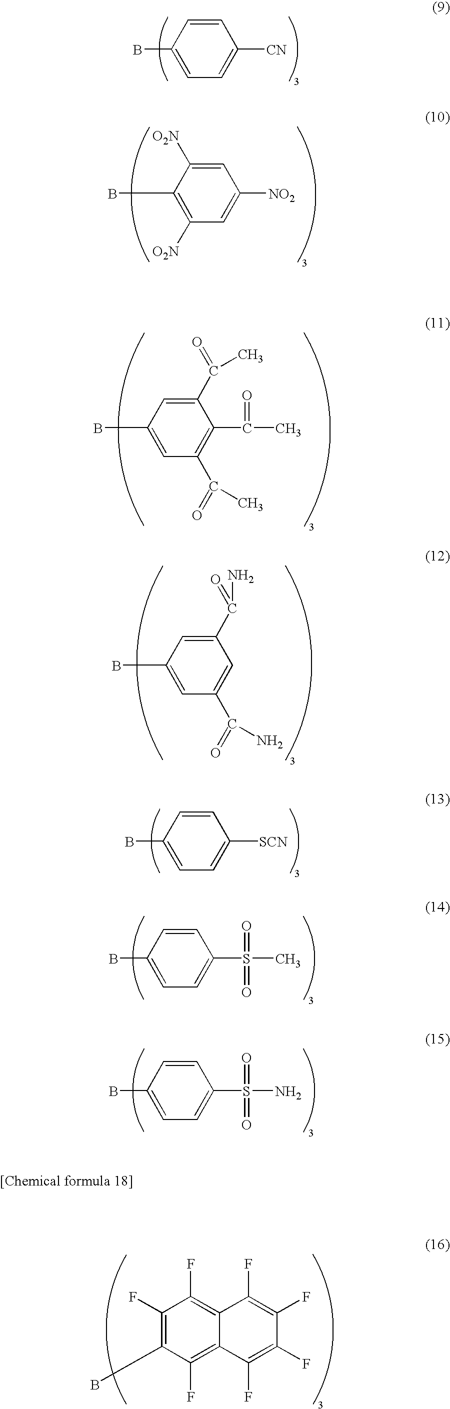

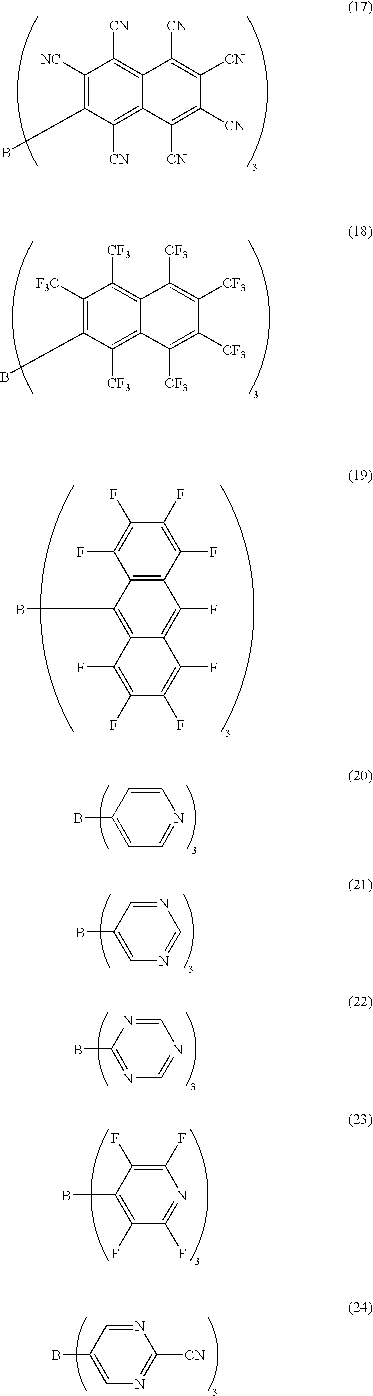

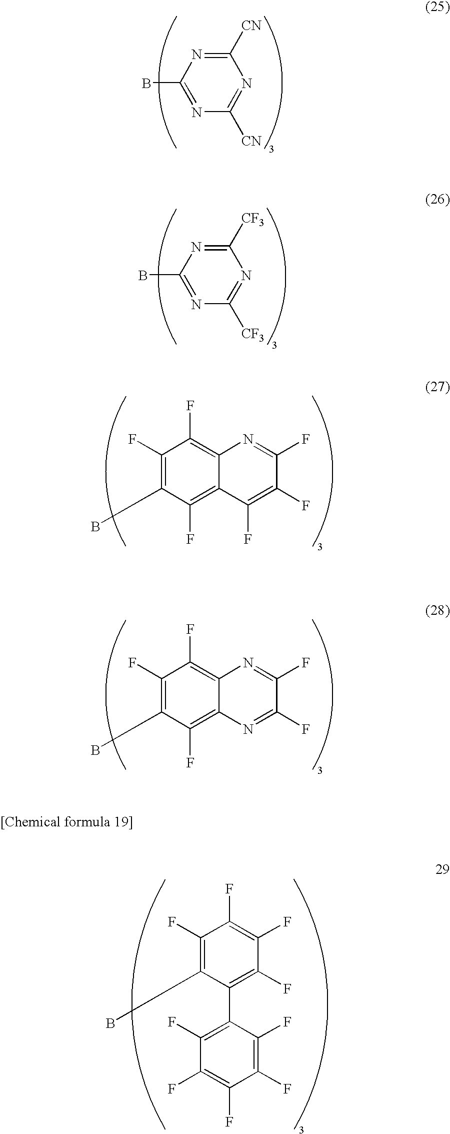

(30) An ionic compound numbered A-1 described in a table in a column of a paragraph “0059” of a specification of Japanese Patent Application 2004-68958.

Among them, compounds shown below are particularly favorable.

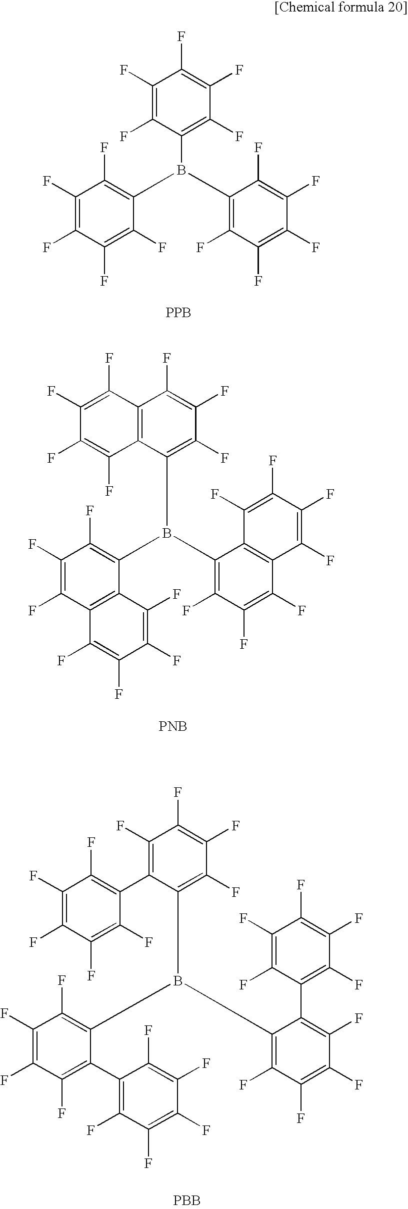

(30) The ionic compound numbered A-1 described in the table in the column of the paragraph “0059” of the specification of Japanese Patent Application 2004-68958.

Moreover, specific examples of the electron acceptor include compounds shown below, which are one type of compound or two or more thereof selected from the group consisting of halogenated metals, Lewis acids, organic acids, salts of arylamines and halogenated metals, and salts of arylamines and Lewis acids.

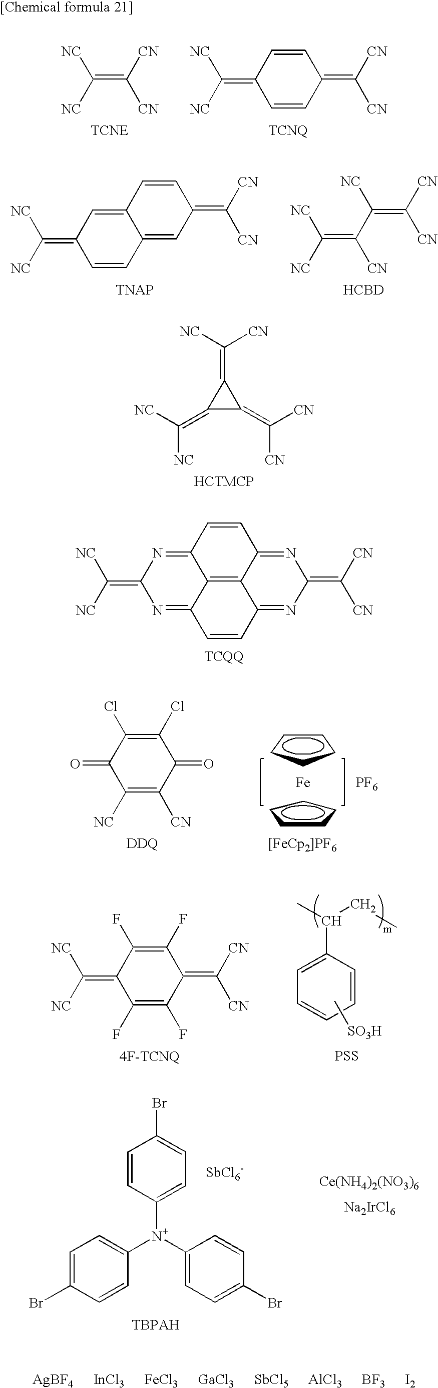

Incidentally, content of the electron acceptor relative to the hole injection/transport materials is usually 0.1 mol % or more, and favorably 1 mol % or more. Note that the content is usually 100 mol % or less and favorably 40 mol % or less.

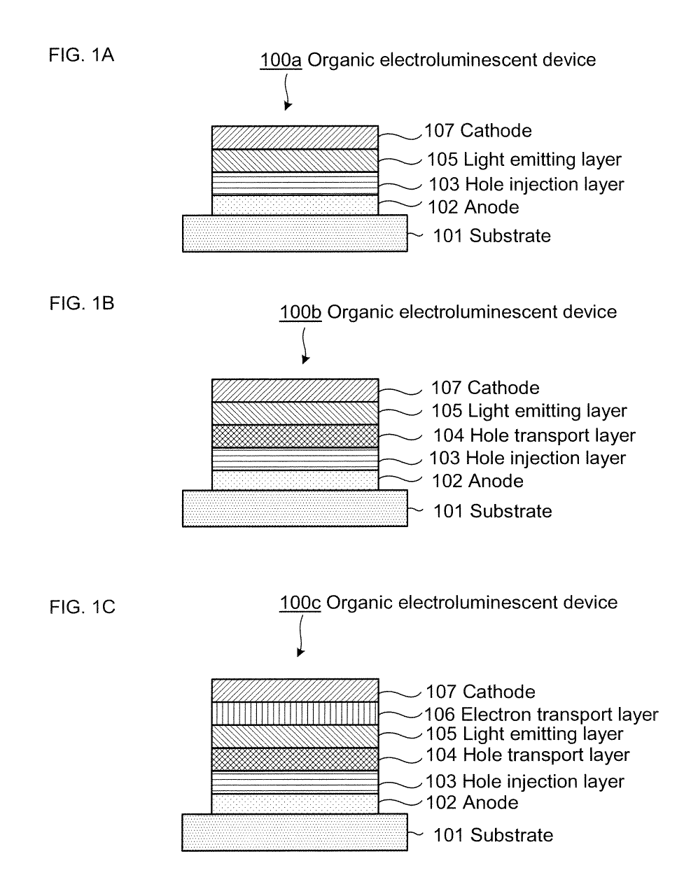

The electroluminescent device prepared using the compositions for the organic electroluminescent device where the present embodiments are applied will be described next. FIGS. 1A to 1C are diagrams describing the organic electroluminescent device with a thin layer formed by the wet film forming method using the compositions for the organic electroluminescent device where the present embodiments are applied. The organic electroluminescent device 100a shown in FIG. 1A has a substrate 101, an anode 102 sequentially laminated on the substrate 101, a hole injection layer 103, a light emitting layer 105, and a cathode 107.

The substrate 101 is a support of the organic electroluminescent device 100a. Materials for forming the substrate 101 include quartz plates, glass plates, metal plates, metal foils, plastic films and plastic sheets. Among them, glass plates and transparent plastic sheets formed of polyesters, poly(meth)acrylate, polycarbonate, polysulfone and so on are favorable. Note that when plastic is used as the substrate 101, it is favorable to provide fine silicon oxide films and so forth on one surface or on both surfaces of the substrate 101 to enhance gas barrier properties.

The anode 102 is provided on the substrate 101 and plays a role in injecting holes into the hole injection layer 103. Materials for the anode 102 include metals such as aluminum, gold, silver, nickel, palladium, platinum; conductive metal oxides like oxides of indium and/or tin; halogenated metals such as copper iodide; carbon black; and conductive polymers such as poly(3-methylthiophene), polypyrrole, and polyaniline. Forming methods of the anode 102 include usual sputtering onto the substrate 101, vacuum deposition, and so on; a method of applying an appropriate binder resin solution dispersing metal particles of silver, particles of copper iodide and so on, carbon black, particles of conductive metal oxides or fine powder of conductive polymers and so on, onto the substrate 101; a method of forming a conductive polymer thin film directly onto the substrate 101 by electrolytic polymerization; and a method of applying a conductive polymer solution onto the substrate 101. Note that the anode 102 usually has a transmittance of visible light of 60% or higher, and especially favorable when the transmittance is 80% or higher. A thickness of the anode 102 is usually 1000 nm or less, and favorably 500 nm or less and usually 5 nm or more and favorably 10 nm or more.

The hole injection layer 103 is provided on the anode 102 and is favorably formed by the wet film forming method using the compositions of the organic electroluminescent device where the present embodiments are applied. The hole injection layer 103 is favorably formed using the hole injection/transport materials and the electron acceptor, which is capable of oxidizing these hole injection/transport materials. A film thickness of the hole injection layer 103 formed as described so far is usually 5 nm or more, favorably 10 nm or more. Note that the thickness is usually 1000 nm or less and favorably 500 nm or less.

The light emitting layer 105 is provided on the hole injection layer 103 and is formed from materials efficiently recombining electrons injected from the cathode 107 and holes transported from the hole injection layer 103 in between electrodes where an electric field is given, and efficiently emitting light due to the recombination. Materials forming the light emitting layer 105 include low molecular light emitting materials such as metal complexes like an aluminum complex of 8-hydroxyquinoline, metal complexes of 10-hydroxybenzo[h]quinoline, bisstyrylbenzene derivatives, bisstyryl arylene derivatives, metal complexes of (2-hydroxyphenyl)benzothiazole, and silole derivatives; mixtures of light emitting materials, electron transfer materials and polymer compounds such as poly(p-phenylenevinylene), poly[2- methoxy-5-(2-ethylhexyloxy)-1,4-phenylenevinylene], and poly(3-alkylthiophene) and polyvinylcarbazole.

Moreover, for example, by adopting the metal complexes like the aluminum complexes of 8-hydroxyquinoline as a host material and by doping 0.1 to 10 weight % of naphthacene derivatives like rubrene and quinacridone derivatives, and fused polycyclic aromatic ring like perylene and so on in the host material, luminescent properties, especially a driving stability of the device can be greatly improved. Thin films are formed by applying these materials onto the hole injection layer 103 by either the vacuum deposition method or the wet film forming method. A film thickness of the light emitting layer 105 formed as described so far is usually 10 nm or more, and favorably 30 nm or more. Note that the thickness is usually 200 nm or less and favorably 100 nm or less.

The cathode 107 plays a role in injecting electrons into the light emitting layer 105. Metals with low work function are favorable as materials used as the cathode 107 and appropriate metals such as tin, magnesium, indium, calcium, aluminum, and silver or their alloys are used, for example. Specific examples include low work function alloys such as magnesium-silver alloy, magnesium-indium alloy, and aluminum-lithium alloy. A film thickness of the cathode 107 is usually similar to that of the anode 102. In order to protect the cathode 107 formed from low work function metals, further lamination of metal layers thereon with high work function and being stable to air is effective in increasing stability of the device. Metals such as aluminum, silver, copper, nickel, chromium, gold, and platinum are used for this purpose. Furthermore, efficiency of the device can be improved by inserting an ultrathin insulating film (film thickness 0.1 to 5 nm) formed of LiF, MgF₂ and Li₂O and so forth on an interface between the cathode 107 and the light emitting layer 105.

FIG. 1B is a diagram for explaining a function-separated type luminescent device. In an organic electroluminescent device 100b shown in FIG. 1B, a hole transport layer 104 is provided in between the hole injection layer 103 and the light emitting layer 105 in order to improve luminescence properties of the device and other layers have similar structures to those of the organic electroluminescent device 100a shown in FIG. 1A. Materials for the hole transport layer 104 needs to be materials with high hole injection efficiency from the hole injection layer 103 and also capable of efficiently transporting injected holes. The materials are required to have low ionization potential, high hole mobility, excellent stability, and also difficulties in forming impurities during manufacturing or while in use, which are to become a trap. Moreover, since the layer 104 directly contacts with the light emitting layer 105, it is desirable not to contain any material quenching luminescence.

Examples of the hole injection/transport materials forming the hole transport layer 104 include similar compounds to those shown as examples of the hole injection/transport materials in the compositions for the organic electroluminescent device where the present embodiments are applied. Moreover, polymer materials such as polyarylene ether sulfone containing polyvinylcarbazole, polyvinyl triphenylamine, and tetraphenylbenzidine are also included. The hole transport layer 104 is formed by laminating these hole injection/transport materials onto the hole injection layer 103 by the wet film forming method or the vacuum deposition method. The film thickness of the hole transport layer 104 formed as described so far is usually 10 nm or more, and favorably 30 nm or more. Note that the thickness is usually 300 nm or less and favorably 100 nm or less.

FIG. 1C is a diagram for explaining function-separated type luminescence device of another embodiment. In an organic electroluminescent device 100c shown in FIG. 1C, an electron transport layer 106 is provided in between the light emitting layer 105 and the cathode 107 and other layers have similar structures to those of the organic electroluminescent device 100b shown in FIG. 1B. Compounds used for the electron transport layer 106 need to inject electrons from the cathode 107 with ease and to have further high electron transport capability. Examples of such electron transporting materials include the aluminum complexes of 8-hydroxyquinoline, oxadiazol derivatives, or dispersions dispersing them in resins like polymethylmethacrylate (PMMA), phenanthroline derivatives, 2-t-butyl-9,10-N,N′-dicyano anthraquinonediimine, n-type hydrogenated amorphous silicon carbide, n-type zinc sulfide, and n-type zinc selenide. The film thickness of the electron transport layer 106 is usually 5 nm or more and favorably 10 nm or more. Note that the thickness is usually 200 nm or less and favorably 100 nm or less.

It should be noted that the organic electroluminescent devices 100a to 100c shown in FIGS. 1A to 1C are not limited to those shown in the figures. For example, a structure opposite to those shown in FIGS. 1A to 1C, in other words, the structure where the cathode 107, light emitting layer 105, hole injection layer 103, and anode 102 are laminated in this order on the substrate 101 is also possible. Moreover, it is also possible to provide the organic electroluminescent device in between two substrates, at least one of which is highly transparent. Furthermore, a layer containing the hole injection/transport materials and the electron acceptor is not necessarily the hole injection layer 103 contacting the anode 102 and can be provided in between the anode 102 and the light emitting layer 105 and especially favorable being the hole injection layer 103. Additionally, arbitrary layers can be present between respective layers shown in FIGS. 1A to 1C.

A manufacturing method of the organic electroluminescent devices 100a to 100c having thin layers formed by the wet film forming method using the compositions for the organic electroluminescent device where the present embodiments are applied is described next. The organic electroluminescent devices 100a to 100c are manufactured as follows. The anode 102 is formed by sputtering, vacuum deposition and so forth onto the substrate 101. At least one layer out of the hole injection layer 103 and the hole transport layer 104 is formed on an upper layer of the formed anode 102 by the wet film forming method using the compositions for the organic electroluminescent device containing the hole injection/transport materials and/or the electron acceptor where the present embodiments are applied. The light emitting layer 105 is formed by the vacuum deposition method or the wet film forming method on an upper layer of the formed hole injection layer 103 and/or the hole transport layer 104. The electron transport layer 106 is formed by the vacuum deposition method or the wet film forming method on an upper layer of the formed light emitting layer 105 where necessary. The cathode 107 is formed on the formed electron transport layer 106.

When at least one layer out of the hole injection layer 103 and the hole transport layer 104 is formed by the wet film forming method, coating solutions, in other words, the compositions for the organic electroluminescent device is usually prepared by adding additives such as binder resins that does not trap a hole or coating property improving agents and so on where necessary to the hole injection/transport materials and/or the electron acceptor with predetermined amounts followed by dissolution. At least one layer out of the hole injection layer 103 and the hole transport layer 104 is formed by drying the compositions after applying them onto the anode 102 by the wet film forming methods such as a spin coating method and a dip coating method usually within 24 hours, favorably within 20 hours, more favorably within 12 hours, and especially favorably within 6 hours after preparation.

When compounds such as alcohols, aldehydes or ketones, which are readily oxidized, are present in solutions containing the hole injection/transport materials and/or the electron acceptor, there is a concern that these easily oxidizable compounds react with the electron acceptors. Moreover, these compounds, which are readily oxidized, can also react with cation radicals (this radical generation improves the hole injection property/hole transport property) of the hole injection/transport materials, generated due to a combined use of the hole injection/transport materials and the electron acceptor. It is considered that impurities are formed when the electron acceptor or cation radicals are consumed in the coating solution due to the reactions of these compounds, which are readily oxidized, and solutions are gradually deactivated and their storage stability reduces for this reason. By forming at least one layer out of the hole injection layer 103 and the hole transport layer 104 by the wet film forming method using the solution containing the hole injection/transport materials and the electron acceptor within 20 hours after preparation, the organic electroluminescent devices 100a to 100c can be manufactured in a state where the hole injection/transport materials or the electron acceptor in the solution are stable.

It should be noted that usually from a viewpoint of the hole mobility, content of the binder resins is favorably 50 weight % or less in these layers and more favorably 30 weight % or less and a case where no binder resins are practically contained is most favorable.

In addition, it is favorable since by undergoing further heating step after steps of wet film forming and drying, the layer containing the hole injection/transport materials and/or the electron acceptor is able to activate migration of molecules contained in the obtained film and to achieve a thermally stable thin film structure thereby improving surface smoothness and luminous efficiency of the device.

Specifically, the layer containing the hole injection/transport materials and/or the electron acceptor are heated at a temperature of a glass transition temperature Tg of the used hole injection/transport materials or lower after being formed by the wet film forming method. The heating temperature lower by 10° C. or more than the glass transition temperature Tg of the hole injection/transport materials is favorable. Moreover, it is favorable to treat at 60° C. or higher in order to fully achieve an effect due to the heat treatment. Heating time is usually approximately 1 minute to 8 hours. Since such layer containing the hole injection/transport materials and/or the electron acceptor formed by the wet film forming method has a smooth surface, a problem of short circuit at the time of device preparation caused by surface roughness of the anode 102 formed of ITO and so on can be solved.

### EXAMPLES

The present embodiments are further described specifically below based on examples, comparative examples, and reference examples. Note that the present embodiments are not limited to the descriptions in the examples.

### Reference Example 1

Physical properties of solvents used to prepare the compositions for the organic electroluminescent device where the present embodiments are applied are shown in Table 1.

TABLE 1

| | | Vapor | Water | Surface |
|---|---|---|---|---|
| | | pressure | solubility | tension |
| | Boil- | (mmHg) | (weight %) | (dyn/cm) |
| | ing | (Measurement | (Measurement | (Measurement |
| Solvent name | point | temperature) | temperature) | temperature) |
| (systematic) | (° C.) | (° C.) | (° C.) | (° C.) |
| ethyl | 213 | 0.27 | 0.072 | 35.4 |
| benzoate | | (25) | (25) | (20) |
| (ester) | | | | |
| anisole | 154 | 3.54 | 0.10 | 34.2 |
| (ether) | | (25) | (25) | (30) |
| 2-phenoxyethyl | 260 | 0.01 | — | 38.4 |
| acetate | | (20) | — | (25) |
| (corresponds | | | | |
| to both ether | | | | |
| and ester) | | | | |
| cyclohexanone | 156 | 5 | 9.5 | 34.5 |
| (ketone) | | (25) | (20) | (20) |
| N-methyl | 202 | 0.34 | Dissolve | 41 |
| pyrolidone | | (20) | with an | (25) |
| (ketone) | | | arbitrary | |
| | | | ratio (25) | |

### Example 1

A product (manufactured by GEOMATEC Co., Ltd.; film product formed by use of electron beam; sheet resistance 15Ω), which was 120 nm of transparent indium tin oxides (ITO) conductive film deposited on a glass substrate, was subjected to ultrasonic cleaning in acetone, rinsing in pure water, ultrasonic cleaning in isopropyl alcohol, drying in dry nitrogen and UV/ozone cleaning. Subsequently, a composite solution containing a hole transporting polymer (homopolymer: Mw=27000, Mn=13000) shown in a chemical formula (P1) below and tris(pentafluorophenyl)borane (PPB) as an electron acceptor is spin coated onto this glass substrate under conditions described below to form a uniform thin film with a film thickness of 30 nm. Spin coating was carried out in air. Environmental conditions at this time were temperature of 23° C. and relative humidity of 60%. 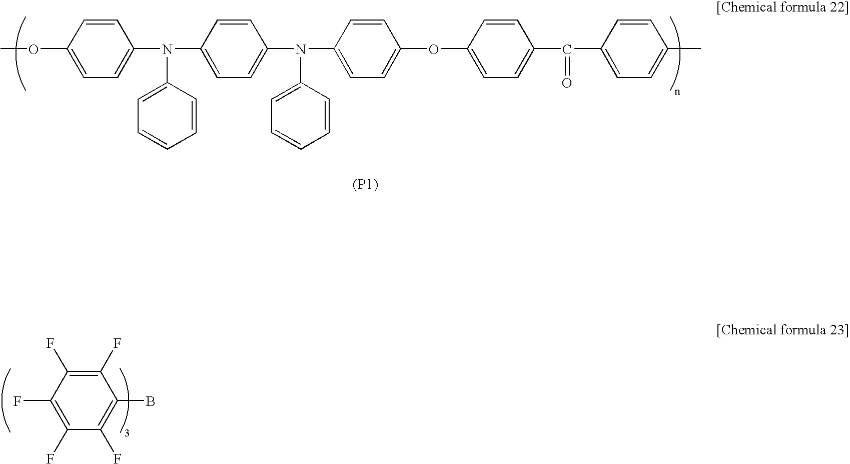
Solvent ethyl benzoate
Coating solution concentration hole transporting polymer 2 weight %/electron acceptor 0.2 weight %
Spinner revolution 1500 rpm
Spinner revolution time 30 seconds
Drying condition Heat drying at 80° C. for 1 minute on a hot plate followed by heat drying at 100° C. for 60 minutes in an oven.

### Example 2

The composite solution containing the hole transporting polymer (P1) and PPB as the electron acceptor is spin coated onto the glass substrate used in Example 1 by similar processes to those of Example 1 under conditions described below to form a uniform thin film with a film thickness of 30 nm. Spin coating was carried out in air. Environmental conditions at this time were temperature of 23° C. and relative humidity of 60%.
Solvent anisole
Coating solution concentration hole transport polymer 1.3 weight %/electron acceptor 0.13 weight %
Spinner revolution 1500 rpm
Spinner revolution time 30 seconds
Drying condition Heat drying at 100° C. for 60 minutes in the oven.

### Example 3

A composite solution containing a hole transport material shown in a chemical formula (H1) and an ionic compound numbered A-1 described in a table in a column of a paragraph “0059” of a specification of Japanese Patent 2004-68958 as the electron acceptor is spin coated onto the glass substrate used in Example 1 by similar processes to those of Example 1 under conditions described below to form a uniform thin film with a film thickness of 30 nm. Spin coating was carried out in air. Environmental conditions at this time were temperature of 23° C. and relative humidity of 55%. 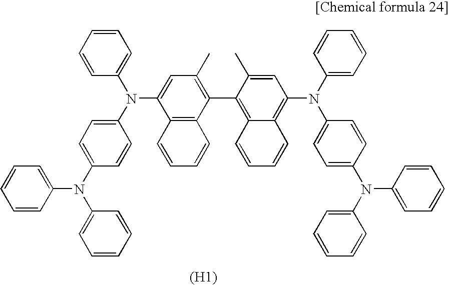
Solvent 2-phenoxyethyl acetate
Coating solution concentration hole transporting polymer 1.2 weight %/electron acceptor 0.24 weight %
Spinner revolution 1500 rpm
Spinner revolution time 30 seconds
Drying condition Heat drying at 80° C. for 5 minutes on the hot plate followed by heat drying at 230° C. for 15 minutes in the oven.

### Comparative Example 1

The composite solution containing the hole transporting polymer (P1) and PPB as the electron acceptor is spin coated onto the above described substrate similarly to Example 1 under conditions described below. Spin coating was carried out in air. Environmental conditions at this time were temperature of 23° C. and relative humidity of 60%.
Solvent N-methyl pyrolidone
Coating solution concentration hole transporting polymer 2 weight %/electron acceptor 0.2 weight %
Spinner revolution 1500 rpm
Spinner revolution time 30 seconds
Drying condition Heat drying at 80° C. for 1 minute on the hot plate followed by heat drying at 100° C. for 60 minutes in the oven.

Marked coating unevenness and bleaching of coating surface were observed on a substrate surface when a film was observed after finishing the spin coating. The following can be considered as a cause for this observation. The coating unevenness occurred by a leveling failure of a liquid film due to high surface tension. Moreover, since a coating solution containing a solvent with high water solubility, a large amount of moisture in the air mixes at the time of drying a coated film. As a result, the hole transporting polymer insoluble in water partially deposit to bleach the coated film.

### Example 4

An organic electroluminescent device having a similar structure to that of the organic electroluminescent device 100c shown in the FIG. 1C is prepared by a method described below.

The product (manufactured by GEOMATEC Co., Ltd.; film product formed by use of electron beam; sheet resistance 15Ω), which was 120 nm of transparent indium tin oxides (ITO) conductive film deposited on a glass substrate, was patterned into a stripe with a width of 2 mm using a usual photolithography technique and hydrochloric acid etching to form an anode. The patterned ITO substrate was subjected to drying in a nitrogen blow after rinsing, which were ultrasonic cleaning in acetone, rinsing in pure water, and ultrasonic cleaning in isopropyl alcohol, in this order and finally to UV/ozone cleaning.

Firstly, a composite solution prepared similarly to that of Example 1 containing the hole transporting polymer (P1) and PPB as the electron acceptor is spin coated onto the above described ITO glass substrate under the same conditions to those of Example 1 to form the hole injection layer with a uniform thin film shape with a film thickness of 30 nm.

Subsequently, the substrate on which the hole injection layer was formed by coating was placed in a vacuum deposition apparatus and rough evacuation of the apparatus was carried out by an oil rotary pump. Thereafter, evacuation was carried out using an oil diffusion pump equipped with a liquid nitrogen trap until a degree of vacuum inside the apparatus became 2×10⁻⁶ Torr (approximately 2.7×10⁻⁴ Pa) or lower. Then 4,4′-bis[N-(9-phenanthyl)-N-phenylamino]biphenyl, which was an aromatic amine compound shown in a chemical formula (H2) below put in a ceramic crucible placed in the apparatus was heated and deposited. The degree of vacuum at the time of deposition was 1.3×10⁻⁶ Torr (approximately 1.7×10⁻⁴ Pa), deposition rate was 0.3 nm/sec and the hole transport layer was formed by laminating a film with a film thickness of 100 nm onto the hole injection layer.

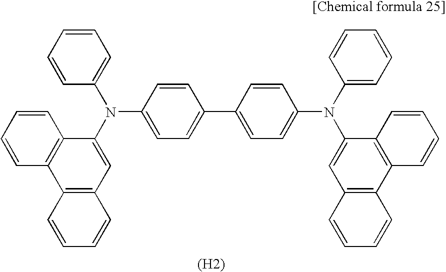

Subsequently, Al(C₉H₆NO)₃ shown in a chemical formula (E1) below, which was an aluminum complex of 8-hydroxyquinoline, as a material for the light emitting layer, and a courmarin derivative shown in a chemical formula (D1) below, as a doping compound are respectively heated and deposited simultaneously using separate crucibles.

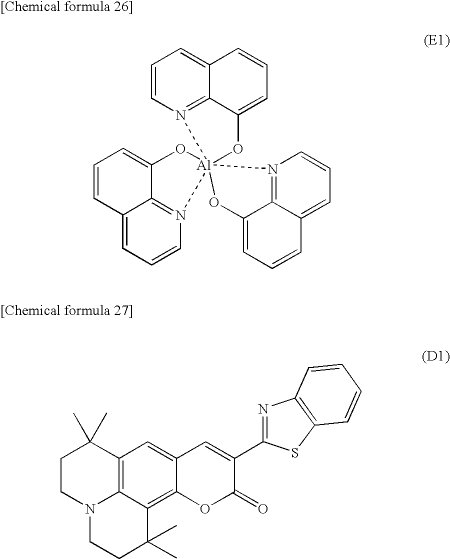

Temperatures of each crucible at this time was controlled within ranges of 282 to 294° C. and 150 to 160° C. for the aluminum complex of 8-hydroxyquinoline and for the compound (D1), respectively. The degree of vacuum at the time of deposition was 1.3×10⁻⁶ Torr (approximately 1.7×10⁻⁴ Pa), deposition rate of the aluminum complex of 8-hydroxyquinoline was 0.1 to 0.3 nm/sec and its deposition time was 2 minutes 24 seconds. As a result, a light emitting layer with a film thinness of 30.2 nm was obtained where the compound (D1) was doped in the complex (E1) by 0.6% film thickness. Furthermore, by stop heating the compound (D1) and controlling the temperature of only the aluminum complex of 8-hdroxyquinoline within the range of 282 to 294° C., the electron transport layer with a film thickness of 45 nm was deposited. The degree of vacuum at that time was 1.3×10⁻⁶ Torr (approximately 1.7×10⁻⁴ Pa), deposition rate was 0.1 to 0.4 nm/sec and deposition time was 2 minutes 43 seconds. Incidentally, substrate temperature at the time of vacuum depositing the hole transport layer, light emitting layer, and electron transport layer was kept at room temperature.

At this point, a device on which the deposition of the electron transport layer was carried out was once taken out of the vacuum deposition apparatus in the air and a stripe-shaped shadow mask with a 2 mm width as a mask for cathode deposition was closely attached to the device so as to be perpendicular to an ITO stripe of the anode and placed in a separate vacuum deposition apparatus. The apparatus was then evacuated until the degree of vacuum inside the apparatus became 2×10⁻⁶ Torr (approximately 2.7×10⁻⁴ Pa) or lower as similar to that at the time of depositing organic layers. Lithium fluoride (LiF) as the cathode was firstly deposited to form a film with a 0.5 nm film thickness on the light emitting layer using a molybdenum boat with a deposition rate of 0.1 nm/sec and the degree of vacuum of 7.0×10⁻⁶ Torr (approximately 9.3×10⁻⁴ Pa). Subsequently aluminum was heated similarly by the molybdenum boat with a deposition rate of 0.5 nm/sec and the degree of vacuum of 1×10⁻⁶ Torr (approximately 1.3×10⁻⁴ Pa) and an aluminum layer with a film thickness of 80 nm was formed to form a cathode. Substrate temperature at the time of depositing the above described two-layer cathode was kept at room temperature. The organic electroluminescent device having a 2 mm×2 mm sized light emission area part was obtained in a way described so far. Luminescent properties of this device are shown in Table 2.

TABLE 2

| | Current | Luminance | | |
|---|---|---|---|---|
| Measurement | density | 100 (cd/m²) | | |
| condition | 250 (mA/cm²) | Luminous | | 10000 |
| Measurement | Luminance | efficiency | | (cd/m²) |
| item | (cd/m²) | (lm/W) | Driving voltage (V) | |
| Example 4 | 31400 | 7.6 | 4.3 | 12.1 |
| Example 5 | 28600 | 8.8 | 3.6 | 11.1 |
| Comparative | 36800 | 7.4 | 4.7 | 14.0 |
| Example 2 | | | | |

Table 2 shows numeric values of luminance (unit: cd/m²) at a current density of 250 mA/cm², luminescence efficiency (unit: lm/W) and driving voltages (unit: V) at a luminance of 100 cd/m², and driving voltages (unit: V) at a luminance of 10000 cd/m², respectively. It is apparent from the results shown in Table 2 that the device was obtained which emits light with high brightness and high luminescence efficiency at a low voltage.

### Example 5

An organic electroluminescent device having a similar structure to that of the organic electroluminescent device 100c shown in FIG. 1C was prepared in a similar method to that of Example 4 except that the hole injection layer was formed by coating in a similar method to that of Example 2. Luminescent properties of this device are shown in Table 2. It is apparent from the results shown in Table 2 that the device was obtained which emits light with high brightness and high luminescence efficiency with a low voltage.

### Comparative Example 2

An organic electroluminescent device having a similar structure to that of the organic electroluminescent device 100c shown in FIG. 1C was prepared in a similar method to that of Example 4 except that the hole injection layer was formed by using the compositions containing the hole transporting polymer (P1) and PPB as the electron acceptor by spin coating under conditions described below. Note that environmental conditions at the time of film formation of the hole injection layer were temperature of 23° C. and relative humidity of 60%. A uniform thin film with a film thickness of 30 nm was obtained as a result. Luminescent properties of this device are shown in Table 2.
Solvent cyclohexanone
Coating solution concentration hole transporting polymer 1 weight %/electron acceptor 0.1 weight %
Spinner revolution 1500 rpm
Spinner revolution time 30 seconds
Drying condition Heat drying at 100° C. for 60 minutes in the oven.
   It is apparent from the results shown in Table 2 that a driving voltage at a luminescence brightness of 10000 cd/m² is high in this device.

### Example 6

An organic electroluminescent device having a similar structure to that of the organic electroluminescent device 100c shown in FIG. 1C was prepared with a method described below.

Firstly, an anode was patterned on an ITO glass substrate in a similar method to that of Example 4. Then a composite solution prepared in a similar way to the Example 3 and containing the hole transport material (H1) and the ionic compound numbered A-1 described in the table in the column of the paragraph “0059” of the specification of Japanese Patent 2004-68958 as the electron acceptor was spin coated under similar conditions to those of Example 3 to form the hole injection layer having a uniform thin film-shape with a film thickness of 30 nm.

Subsequently, the substrate on which the hole injection layer was formed by coating was placed in a vacuum deposition apparatus and rough evacuation of the apparatus was carried out by the oil rotary pump. Thereafter, evacuation was carried out using the oil diffusion pump equipped with the liquid nitrogen trap until the degree of vacuum inside the apparatus became 2×10⁻⁶ Torr (approximately 2.7×10⁻⁴ Pa) or lower. Then an aromatic amine compound shown in a chemical formula (H2) above put in the ceramic crucible placed in the apparatus was heated and deposited. The degree of vacuum at the time of deposition was 1.3×10⁻⁶ Torr (approximately 1.7×10⁻⁴ Pa), deposition rate was 0.3 nm/sec and the hole transport layer was formed by laminating a film with a film thickness of 45 nm onto the hole injection layer.

Subsequently, the aluminum complex of 8-hydroxyquinoline shown in a chemical formula (E1) below as the material for the light emitting layer was heated and the light emitting layer with a film thickness of 60 nm was deposited. Temperature of the crucible at this time was controlled within a range of 282 to 294° C. The degree of vacuum at the time of deposition was 1.3×10⁻⁶ Torr (approximately 1.7×10⁻⁴ Pa), deposition rate was 0.1 to 0.3 nm/sec and its deposition time was 4 minute 30 seconds. Incidentally, substrate temperature at the time of vacuum depositing the hole transport layer, light emitting layer, and electron transport layer was kept at room temperature.

At this point, the device, in which the deposition of the electron transport layer was carried out was once taken out of the vacuum deposition apparatus in the air and a two-layer type cathode formed from lithium fluoride and aluminum was deposited in a similar method to that of Example 4. Substrate temperature at the time of deposition was kept at room temperature. The organic electroluminescent device having a 2 mm×2 mm sized light emission area part was obtained in a way described so far. Luminescent properties of this device are shown in Table 3.

TABLE 3

| | Current | Luminance | | |
|---|---|---|---|---|
| Measurement | density | 100 (cd/m²) | | |
| condition | 250 (mA/cm²) | Luminous | | 10000 |
| Measurement | Luminance | efficiency | | (cd/m²) |
| item | (cd/m²) | (lm/W) | Driving voltage (V) | |
| Example 6 | 6810 | 2.1 | 3.9 | 5.5 |
| Comparative | 8990 | 2.5 | 4.2 | 6.3 |
| Example 3 | | | | |

Table 3 shows numeric values of luminance (unit: cd/m²) at a current density of 250 mA/cm², luminescence efficiency (unit: lm/W) and driving voltages (unit: V) at a luminance of 100 cd/m², and driving voltages (unit: V) at a luminance of 1000 cd/m², respectively. It is apparent from the results shown in Table 3 that the device was obtained, which emits light at a low voltage.

### Comparative Example 3

An organic electroluminescent device having a similar structure to that of the organic electroluminescent device 100c shown in the FIG. 1C is prepared by a method described below.

Firstly, the hole injection layer with a film thickness of 30 nm containing the hole transporting polymer (P1) and PPB as the electron acceptor was formed by coating in a similar method to that of Comparative Example 2.

Subsequently, the substrate on which the hole injection layer was formed by coating was placed in the vacuum deposition apparatus and rough evacuation of the apparatus was carried out by the oil rotary pump. Thereafter, evacuation was carried out using the oil diffusion pump equipped with the liquid nitrogen trap until the degree of vacuum inside the apparatus became 2×10⁻⁶ Torr (approximately 2.7×10⁻⁴ Pa) or lower. Then the aromatic amine compound shown in a chemical formula (H2) below put in the ceramic crucible placed in the apparatus was heated and deposited. The degree of vacuum at the time of deposition was 1.3×10⁻⁶ Torr (approximately 1.7×10⁻⁴ Pa), deposition rate was 0.3 nm/sec and the hole transport layer was formed by laminating a film with a film thickness of 40 nm onto the hole injection layer.

Thereafter, the light emitting layer and the two-layer type cathode were deposited in a similar method to that of Example 6 and the organic electroluminescent device having a 2 mm×2 mm sized light emission area part was obtained. Luminescent properties of this device are shown in Table 3. It is apparent from the results shown in Table 3 that the organic electroluminescent device prepared in Comparative Example 3 has the hole transport layer with a thinner film thickness when compared to the organic electroluminescent device prepared in Example 6 and thus, a driving voltage is high at a luminescence brightness of 1000 cd/m² despite the thin film thickness of the overall organic layer.

### Reference Example 2

The product (manufactured by GEOMATEC Co., Ltd.; film product formed by use of electron beam; sheet resistance 15Ω), which was 120 nm of transparent indium tin oxides (ITO) conductive film deposited on a glass substrate, was subjected to ultrasonic cleaning in acetone, rinsing in pure water, ultrasonic cleaning in isopropyl alcohol, drying in dry nitrogen and UV/ozone cleaning. Subsequently, a composite solution containing the hole transporting polymer (homopolymer: Mw=27000, Mn=13000) shown in a chemical formula (P1) below and tris(pentafluorophenyl)borane (PPB) shown in a chemical formula (A1) below as the electron acceptor is spin coated onto this glass substrate under conditions described below to form a uniform thin film with a film thickness of 30 nm. Spin coating was carried out in air. Environmental conditions at this time were temperature of 23° C. and relative humidity of 60%. 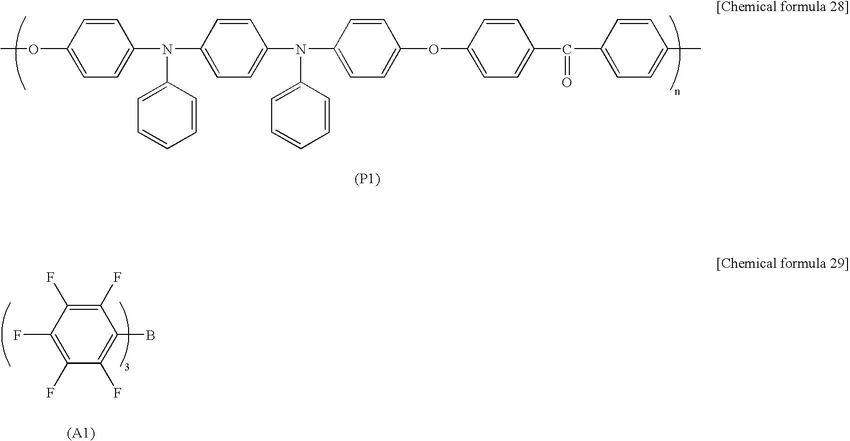
Solvent ethyl benzoate
Coating solution concentration hole transporting polymer 2 weight %/electron acceptor 0.2 weight %
Spinner revolution 1500 rpm
Spinner revolution time 30 seconds
Drying condition Heat drying at 80° C. for 1 minute on the hot plate followed by heat drying at 100° C. for 60 minutes in the oven.

### Reference Example 3

A composite solution containing the hole transporting polymer (P1) and PPB as the electron acceptor is spin coated onto a substrate as similar to Reference Example 2 under conditions described below to form a uniform thin film with a film thickness of 30 nm. Spin coating was carried out in air. Environmental conditions at this time were temperature of 23° C. and relative humidity of 60%.
Solvent cyclohexanone
Coating solution concentration hole transporting polymer 1 weight %/electron acceptor 0.1 weight %
Spinner revolution 1500 rpm
Spinner revolution time 30 seconds
Drying condition Heat drying at 100° C. for 60 minutes in the oven.

### Reference Example 4

A composite solution containing a hole transporting polymer (homopolymer: Mw=17000, Mn=8300) shown in a chemical formula (P2) below and tris(4-bromophenyl)aminium hexachloroantimonate (TBPAH) shown in a chemical formula (A2) as the electron acceptor is spin coated onto this substrate as similar to Reference Example 2 under conditions described below to form a uniform thin film with a film thickness of 15 nm. Spin coating was carried out in air. Environmental conditions at this time were temperature of 23° C. and relative humidity of 60%. 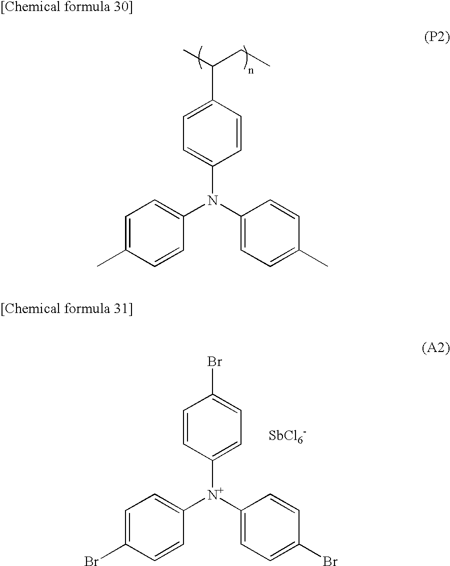
Solvent cyclohexanone
Coating solution concentration hole transporting polymer 0.5 weight %/electron acceptor 0.05 weight %
Spinner revolution 1500 rpm
Spinner revolution time 30 seconds
Drying condition Heat drying at 100° C. for 60 minutes in the oven.

### Reference Example 5

A composite solution containing the hole transporting polymer (P2) and TBPAH as the electron acceptor is spin coated onto the substrate as similar to Reference Example 4 under conditions described below to form a uniform thin film with a film thickness of 15 nm. Spin coating was carried out in air. Environmental conditions at this time were temperature of 23° C. and relative humidity of 60%.
Solvent chloroform
Coating solution concentration hole transporting polymer 0.5 weight %/electron acceptor 0.05 weight %
Spinner revolution 1500 rpm
Spinner revolution time 30 seconds
Drying condition Heat drying at 100° C. for 60 minutes in the oven.

### Example 7

An organic electroluminescent device having a similar structure to that of the organic electroluminescent device 100b shown in the FIG. 1B is prepared by a method described below.

The product (manufactured by GEOMATEC Co., Ltd.; film product formed by use of electron beam; sheet resistance 15Ω), which was 120 nm of transparent indium tin oxides (ITO) conductive film deposited on a glass substrate, was patterned into the stripe with a width of 2 mm using the usual photolithography technique and hydrochloric acid etching to form the anode. The patterned ITO substrate was subjected to drying in the nitrogen blow after rinsing, which were ultrasonic cleaning in acetone, rinsing in pure water, and ultrasonic cleaning in isopropyl alcohol, in this order and finally to UV/ozone cleaning.

Firstly, the composite solution prepared similarly to that of Reference Example 2 containing the hole transporting polymer (P1) and PPB as the electron acceptor is spin coated onto the above described ITO glass substrate under the same conditions to those of Reference Example 2. Incidentally, the solution where the hole transporting polymer (P1) and PPB were dissolved in ethyl benzoate, which was a solvent, and left to stand for 30 minutes after dissolution was used for the composite solution. The hole injection layer with a uniform thin film shape with a film thickness of 30 nm was formed by this spin coating.

Subsequently, the substrate on which the hole injection layer was formed by coating was placed in the vacuum deposition apparatus and rough evacuation of the apparatus was carried out by the oil rotary pump. Thereafter, evacuation was carried out using the oil diffusion pump equipped with the liquid nitrogen trap until the degree of vacuum inside the apparatus became 2×10⁻⁶ Torr (approximately 2.7×10⁻⁴ Pa) or lower. Then 4,4′-bis[N-(9-phenanthyl)-N-phenylamino]biphenyl, which is the aromatic amine compound shown in a chemical formula (H2) below put in the ceramic crucible placed in the apparatus was heated and deposited. The degree of vacuum at the time of deposition was 1.3×10⁻⁶ Torr (approximately 1.7×10⁻⁴ Pa), deposition rate was 0.3 nm/sec and the hole transport layer was completed by laminating a film with a film thickness of 40 nm onto the hole injection layer.

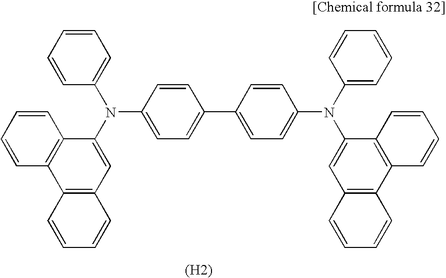

Subsequently, Al(C₉H₆NO)₃ shown in a chemical formula (E1) below, which is the aluminum complex of 8-hydroxyquinoline, as the material for the light emitting layer, was heated and deposited using the crucible. Temperature of the crucible at this time was controlled within a range of 282 to 294° C. The degree of vacuum at the time of deposition was 1.3×10⁻⁶ Torr (approximately 1.7×10⁻⁴ Pa), deposition rate was 0.1 to 0.3 nm/sec and its deposition time was 2 minutes 40 seconds. As a result, the light emitting layer with a film thinness of 60 nm was obtained.

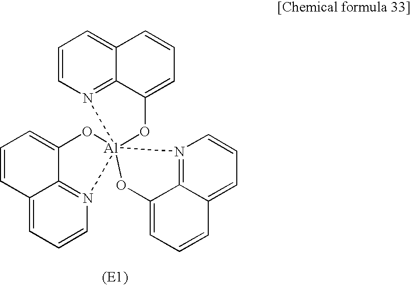

Substrate temperature at the time of vacuum depositing the above described hole transport layer and the light emitting layer was kept at room temperature. At this point, the stripe-shaped shadow mask with a 2 mm width as the mask for cathode deposition was closely attached to the device on which the deposition of the light emitting layer was carried, so as to be perpendicular to the ITO stripe of the anode and placed in a separate vacuum deposition apparatus. The apparatus was then evacuated until the degree of vacuum inside the apparatus became 2×10⁻⁶ Torr (approximately 2.7×10⁻⁴ Pa) or lower as similar to the case of the organic layers. Lithium fluoride (LiF) was firstly deposited as a cathode to form a film with a 0.5 nm film thickness on the light emitting layer using the molybdenum boat with a deposition rate of 0.1 nm/sec and the degree of vacuum of 7.0×10⁻⁶ Torr (approximately 9.3×10⁻⁴ Pa). Subsequently aluminum was heated similarly by the molybdenum boat with a deposition rate of 0.5 nm/sec and the degree of vacuum of 1×10⁻⁵ Torr (approximately 1.3×10⁻³ Pa) and the aluminum layer with a film thickness of 80 nm was formed to form a cathode. Substrate temperature at the time of depositing the above described two-layer type cathode was kept at room temperature. The organic electroluminescent device having a 2 mm×2 mm sized light emission area part was obtained in a way described so far. Luminescent properties of this device are shown in Table 4.

Table 4 shows numeric values of luminance (unit: cd/m²) at a current density of 250 mA/cm², luminescence efficiency (unit: lm/W) at a luminance of 100 cd/m², luminance /current density (unit: cd/A) and driving voltages (unit: V), respectively.

TABLE 4

| | Current | Luminance | | |
|---|---|---|---|---|
| Measurement | density | 100 (cd/m²) | | |
| condition | 250 (mA/cm²) | Luminous | Luminance/ | Driving |
| Measurement | Luminance | efficiency | current density | voltage |
| item | (cd/m²) | (lm/W) | (cd/A) | (V) |
| Example 7 | 7300 | 2.1 | 2.8 | 4.4 |
| Example 8 | 9700 | 2.2 | 3.1 | 4.5 |
| Example 9 | 7000 | 1.8 | 2.3 | 4.0 |
| Comparative | 9900 | 1.2 | 3.0 | 7.8 |
| Example 4 | | | | |

### Example 8

An organic electroluminescent device having a similar structure to that of the organic electroluminescent device 100b shown in the FIG. 1B is prepared in a similar way to that of Example 7 except that the hole injection layer was formed by using a composite solution, where the hole transporting polymer (P1) and PPB are dissolved in ethyl benzoate, which was a solvent, and kept after dissolution at 23° C. for 4 weeks while shielding light. Luminescent properties of this device are shown in Table 4.

It is apparent from Table 4 that the organic electroluminescent device was obtained with a driving voltage, which almost equals to that of the device described in Example 7, and with equivalent properties even when its coating composition was prepared with a method described in Reference Example 2 and was kept at 23° C. for two weeks.

### Example 9

As the composition shown in Reference Example 3, an organic electroluminescent device having a similar structure to that of the organic electroluminescent device 100b shown in the FIG. 1B is prepared in a similar way to that of Example 7 except the use of a coating solution, where the hole transporting polymer (P1) as a coating solution and PPB as the electron acceptor are mixed in cyclohexanone, which was a solvent, and 30 minutes after the mixing, the hole injection layer was formed by film formation under similar conditions to those of Reference Example 3. Luminescent properties of this device are shown in Table 4.

### Comparative Example 4

As the composition shown in Reference Example 3, an organic electroluminescent device having a similar structure to that of the organic electroluminescent device 100b shown in the FIG. 1B is prepared in a similar way to that of Example 7 except that the hole injection layer was formed under similar conditions to those of Reference Example 3 by using a composite solution, where the hole transporting polymer (P1) and PPB are dissolved in cyclohexanone, which was a solvent, and kept after the dissolution at 23° C. for 4 weeks while shielding light. Luminescent properties of this device are shown in Table 4. A driving voltage of this device exhibited a higher value than that of the device described in Example 9.

### Example 10

An organic electroluminescent device having a similar structure to that of the organic electroluminescent device 100c shown in the FIG. 1C is prepared by a method described below.

The product (manufactured by GEOMATEC Co., Ltd.; film product formed by use of electron beam; sheet resistance 15Ω), which was 120 nm of transparent indium tin oxides (ITO) conductive film deposited on a glass substrate, was patterned into the stripe of a width of 2 mm using the usual photolithography technique and hydrochloric acid etching to form the anode. The patterned ITO substrate was subjected to drying in the nitrogen blow after rinsing, which were ultrasonic cleaning in acetone, rinsing in pure water, and ultrasonic cleaning in isopropyl alcohol in this order, and finally to UV/ozone cleaning.

Firstly, the composite solution prepared similarly to Reference Example 3 containing the hole transporting polymer (P1) and PPB as the electron acceptor is spin coated onto the above described ITO glass substrate under the same conditions to those of Example 8. Note that the solution where the hole transporting polymer (P1) and PPB were dissolved in cyclohexanone, which was a solvent, and was kept at 23° C. for one hour was used here as the coating solution. The hole injection layer with a uniform thin film shape with a film thickness of 30 nm was formed by this spin coating.

Subsequently, the substrate on which the hole injection layer was formed by coating was placed in the vacuum deposition apparatus. After carrying out rough evacuation of the apparatus by the oil rotary pump, evacuation using the oil diffusion pump equipped with the liquid nitrogen trap was performed until the degree of vacuum inside the apparatus became 2×10⁻⁶ Torr (approximately 2.7×10⁻⁴ Pa) or lower. Then the compound (H1) below put in a ceramic crucible placed in the apparatus was heated and deposited. The degree of vacuum at the time of deposition was 1.3×10⁻⁶ Torr (approximately 1.7×10⁻⁴ Pa), deposition rate was 0.3 nm/sec and the hole transport layer was formed by laminating a film with a film thickness of 40 nm onto the hole injection layer.

Subsequently, the compound (E1) as the material for the light emitting layer, and rubrene shown in a chemical formula (D1) below are respectively heated and deposited simultaneously using separate crucibles. Temperatures of each crucible at this time were controlled within ranges of 282 to 294° C. and 180 to 190° C. for the compound (E1) and for the compound (D1), respectively. The degree of vacuum at the time of deposition was 1.3×10⁻⁶ Torr (approximately 1.7×10⁻⁴ Pa), deposition rate was 0.1 to 0.3 nm/sec and deposition time was 2 minutes 45 seconds. As a result, the light emitting layer with a film thickness of 30.7 nm was obtained where the compound (D1) was doped in the complex (E1) by 2.5% film thickness.

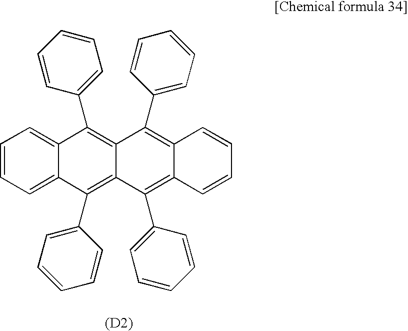

Furthermore, by stop heating the compound (D2), and controlling only the temperature of the aluminum complex of 8-hdroxyquinoline within the range of 282 to 294° C., the electron transport layer 106 with a film thickness of 45 nm was deposited. The degree of vacuum at that time was 1.3×10⁻⁶ Torr (approximately 1.7×10⁻⁴ Pa), deposition rate was 0.1 to 0.4 nm/sec and deposition time was 2 minutes 52 seconds. Substrate temperature at the time of vacuum depositing the hole transport layer, light emitting layer, and electron transport layer was kept at room temperature.

At this point, the stripe-shaped shadow mask with a 2 mm width as the mask for cathode deposition was closely attached to the device on which the deposition of the electron transport layer was carried out, so as to be perpendicular to the ITO stripe of the anode and placed in a separate vacuum deposition apparatus. The apparatus was then evacuated until the degree of vacuum inside the apparatus became 2×10⁻⁶ Torr (approximately 2.7×10⁻⁴ Pa) or lower as similar to the case of the organic layers. Lithium fluoride (LiF) as the cathode was firstly deposited to form a film with a 0.5 nm film thickness on the light emitting layer using the molybdenum boat with a deposition rate of 0.1 nm/sec and the degree of vacuum of 7.0×10⁻⁶ Torr (approximately 9.3×10⁻⁴ Pa). Subsequently aluminum was heated similarly by the molybdenum boat with a deposition rate of 0.5 nm/sec and the degree of vacuum of 1×10⁻⁵ Torr (approximately 1.3×10⁻³ Pa) and the aluminum layer with a film thickness of 80 nm was formed to complete a cathode. Substrate temperature at the time of depositing the above described two-layer type cathode was kept at room temperature. The organic electroluminescent device having a 2 mm×2 mm sized light emission area part was obtained in a way described so far. Luminescent properties of this device are shown in Table 5.

TABLE 5

| | Current | Luminance | | |
|---|---|---|---|---|
| Measurement | density | 100 (cd/m²) | | |
| condition | 250 (mA/cm²) | Luminous | Luminance/ | Driving |
| Measurement | Luminance | efficiency | current density | voltage |
| item | (cd/m²) | (lm/W) | (cd/A) | (V) |
| Example 10 | 13900 | 4.8 | 7.1 | 4.7 |
| Example 11 | 13400 | 4.5 | 6.8 | 4.8 |
| Comparative | 14500 | 4.4 | 7.2 | 5.2 |
| Example 5 | | | | |

### Example 11

An organic electroluminescent device having a similar structure to that of the organic electroluminescent device 100c shown in the FIG. 1C is prepared in a similar way to that of Example 10 except that the hole injection layer was formed under similar conditions to those of Reference Example 3 by using the composite solution, where the hole transporting polymer (P1) and PPB are dissolved in cyclohexanone, which was a solvent, with a composition similar to that described in Reference Example 3 and kept after the dissolution at 23° C. for 5 hours. Luminescent properties of this device are shown in Table 5.

It is apparent from Table 5 that the organic electroluminescent device was obtained with a driving voltage, which almost equals to that of the device described in Example 10, and with equivalent properties even when its coating composition was prepared with a method described in Reference Example 3 and was kept at 23° C. for 5 hours.

### Comparative Example 5

An organic electroluminescent device having a similar structure to that of the organic electroluminescent device 100c shown in the FIG. 1C is prepared in a similar way to that of Example 10 except that the hole injection layer was formed by film formation under similar conditions to those of Reference Example 3 using the composite solution, where the hole transporting polymer (P1) and PPB are dissolved in cyclohexanone, which was a solvent, with a composition similar to that described in Reference Example 3 and kept after the dissolution at 23° C. for 24 hours while shielding light. Luminescent properties of this device are shown in Table 5.

It is apparent that a driving voltage of this device exhibited higher value than that of the device described in Example 10.

### Example 12

An organic electroluminescent device having a similar structure to that of the organic electroluminescent device 100b shown in the FIG. 1B is prepared by a method described below.

The product (manufactured by GEOMATEC Co., Ltd.; film product formed by use of electron beam; sheet resistance 15Ω), which was 120 nm of transparent indium tin oxides (ITO) conductive film deposited on a glass substrate, was patterned into the stripe with a width of 2 mm using the usual photolithography technique and hydrochloric acid etching to form the anode. The patterned ITO substrate was subjected to drying in the nitrogen blow after rinsing, which were ultrasonic cleaning in acetone, rinsing in pure water, and ultrasonic cleaning in isopropyl alcohol in this order, and finally to UV/ozone cleaning.

Firstly, the hole injection layer with a film thickness of 15 nm was formed by using the coating solution, where the hole transporting polymer (P2) and TBPAH as the electron acceptor are dissolved in cyclohexanone, which was a solvent, and by coating the hole injection layer, 30 minutes after the dissolution. Subsequently, the substrate on which the hole injection layer was formed by coating was placed in the vacuum deposition apparatus and rough evacuation of the apparatus was carried out by the oil rotary pump. Thereafter, evacuation using the oil diffusion pump equipped with the liquid nitrogen trap was carried out until the degree of vacuum inside the apparatus became 2×10⁻⁶ Torr (approximately 2.7×10⁻⁴ Pa) or lower. Then 4,4′-bis[N-(1-naphthyl)-N-phenylamino]biphenyl, which is the aromatic amine compound shown in a chemical formula (H3) below put in the ceramic crucible placed in the apparatus was heated and deposited. The degree of vacuum at the time of deposition was 1.3×10^{31 6} Torr (approximately 1.7×10⁻⁴ Pa), deposition rate was 0.3 nm/sec and the hole transport layer was completed by laminating a film with a film thickness of 40 nm onto the hole injection layer.

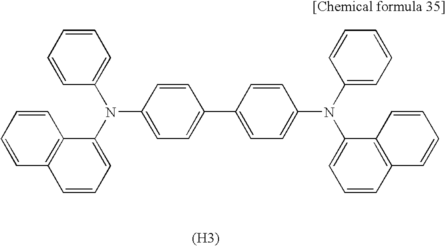

Subsequently, the compound (E1) as the material for the light emitting layer was deposited. Temperature of the crucible at this time was controlled within a range of 282 to 294° C. The degree of vacuum at the time of deposition was 1.3×10⁻⁶ Torr (approximately 1.7×10⁻⁴ Pa), deposition rate was 0.1 to 0.3 nm/sec and deposition time was 5 minutes 5 seconds. As a result, the light emitting layer with a film thickness of 60 nm was formed. Substrate temperature at the time of vacuum depositing the above described hole transport layer and light emitting layer was kept at room temperature.

At this point, the stripe-shaped shadow mask with a 2 mm width as the mask for cathode deposition was closely attached to the device on which the deposition of the light transmitting layer was carried out, so as to be perpendicular to the ITO stripe of the anode and placed in a separate vacuum deposition apparatus. The apparatus was then evacuated until the degree of vacuum inside the apparatus became 2×10⁻⁶ Torr (approximately 2.7×10⁻⁴ Pa) or lower as similar to the case of the organic layers. Lithium fluoride (LiF) as a cathode was firstly deposited to form a film with a 0.5 nm film thickness on the light emitting layer using the molybdenum boat with a deposition rate of 0.1 nm/sec and the degree of vacuum of 7.0×10⁻⁶ Torr (approximately 9.3×10⁻⁴ Pa). Subsequently aluminum was heated similarly by the molybdenum boat with a deposition rate of 0.5 nm/sec and the degree of vacuum of 1×10⁻⁵ Torr (approximately 1.3×10⁻³ Pa) and the aluminum layer with a film thickness of 80 nm was formed to complete the cathode. Substrate temperature at the time of depositing the above described two-layer type cathode was kept at room temperature.

The organic electroluminescent device having a 2 mm×2 mm sized light emission area part was obtained in a way described so far. Luminescent properties of this device are shown in Table 6.

### Comparative Example 6

An organic electroluminescent device having a similar structure to that of the organic electroluminescent device 100b shown in the FIG. 1B is prepared in a similar way to that of Example 12 except that the hole transporting polymer (P2) and TBPAH were dissolved in chloroform, which was a solvent, with a composition described in Reference Example 4, and after being kept for 30 minutes, the hole injection layer was formed by film formation under similar conditions to those of Reference Example 4. Luminescent properties of this device are shown in Table 6. It is apparent from the results shown in Table 6 that a driving voltage of this device exhibited a higher value than that of the device described in Example 12.

TABLE 6

| | Current | Luminance | | |
|---|---|---|---|---|
| Measurement | density | 100 (cd/m²) | | |
| condition | 250 (mA/cm²) | Luminous | Luminance/ | Driving |
| Measurement | Luminance | efficiency | current density | voltage |
| item | (cd/m²) | (lm/W) | (cd/A) | (V) |
| Example 12 | 8000 | 1.5 | 3.0 | 6.2 |
| Comparative | 6800 | 1.1 | 2.9 | 8.7 |
| Example 6 | | | | |

What is claimed is:

1. Compositions for an organic electroluminescent device, containing hole injection/transport materials and/or an electron acceptor forming at least one layer out of a hole injection layer and a hole transport layer of the organic electroluminescent device, and
a solvent dissolving the hole injection/transport materials and/or the electron acceptor,
wherein a concentration in the compositions of at least one solvent selected from (1) and (2) described below contained in the solvent is 10 weight % or higher:
(1) an ether solvent and/or ester solvent (2) a solvent whose water solubility at 25° C. is 1 weight % or less.

2. The compositions for the organic electroluminescent device according to claim 1, wherein the solvent (1), which is the ether solvent and/or ester solvent is a solvent whose water solubility at 25° C. is 1 weight % or less.

3. The compositions for the organic electroluminescent device according to any one of claims 1 and 2, wherein the solvent (1) or (2) is a solvent which satisfies at least one condition selected from (3) to (5) described below.
(3) a solvent whose surface tension is lower than 40 mN/m at 20° C.
(4) a solvent whose vapor pressure is 10 mmHg or lower at 25° C.
(5) a mixed solvent of a solvent whose vapor pressure is 2 mmHg or higher at 25° C. with a solvent whose vapor pressure is lower than 2 mmHg at 25° C.

4. The compositions for the organic electroluminescent device according to any one of claims 1 to 3, wherein the hole injection/transport materials are aromatic amine compounds and the electron acceptor is an aromatic boron compound.

5. The compositions for the organic electroluminescent device according to any one of claims 1 to 4, wherein water content of the compositions is 1 weight % or less.

6. An organic electroluminescent device in which at least an anode, hole injection layer, hole transport layer, light emitting layer, and cathode are laminated on a substrate,
wherein at least one layer out of the hole injection layer and the hole transport layer is formed by a wet film forming method using the compositions for the organic electroluminescent device described in any one of claims 1 to 5.

7. Compositions for an organic electroluminescent device, containing hole injection/transport materials and/or an electron acceptor forming at least one layer out of a hole injection layer and a hole transport layer of the organic electroluminescent device, and
a solvent dissolving the hole injection/transport materials and/or the electron acceptor,
wherein concentration of a quencher deactivating the hole injection/transport materials and/or the electron acceptor, or of a compound generating the quencher, contained in the compositions is 1 weight % or lower.

8. The compositions for the organic electroluminescent device according to claim 7, wherein at least one out of the quencher or the compound generating the quencher is an alcohol solvent, aldehyde solvent, or ketone solvent.

9. The compositions for an organic electroluminescent device according to one of claims 7 and 8, wherein at least one out of the quencher or the compound generating the quencher is a protonic acid or a halogenated solvent.

10. The compositions for an organic electroluminescent device according to any one of claims 7 to 9, wherein the hole injection/transport materials are aromatic amine compounds and the electron acceptor is an aromatic boron compound.

11. A manufacturing method of an organic electroluminescent device using the composition for an organic electroluminescent device according to claim 1 comprising steps of:
forming an anode on a substrate;
forming a hole injection layer on the formed anode, within 20 hours after preparing a composition having the hole injection/transport material and electron acceptor, by a wet film forming method using the composition;
forming a light emitting layer on the formed hole injection layer directly or through another layer; and
forming a cathode on the formed light emitting layer directly or though another layer.
